(19) United States
(12) Patent Application Publication
(10) Pub. No.: US 2026/0047081 A1
(43) Pub. Date: Feb. 12, 2026

(54) SEMICONDUCTOR MEMORY DEVICE

(71) Applicant: Samsung Electronics Co., Ltd., Suwon-si (KR)

(72) Inventors: Kyul Ko, Suwon-si (KR); Jun Soo Kim, Suwon-si (KR); Dae Hyun Moon, Suwon-si (KR); Jeong Hoon Oh, Suwon-si (KR); Sung Ho Jang, Suwon-si (KR)

(21) Appl. No.: 19/093,343

(22) Filed: Mar. 28, 2025

(30) Foreign Application Priority Data
Aug. 12, 2024 (KR) 10-2024-0107294

(51) Int. Cl. H10B 12/00; H10D 64/68

(52) U.S. Cl. CPC H10B 12/488; H10B 12/315; H10B 12/482; H10D 64/691

(57) ABSTRACT

There is provided a semiconductor memory device in which the degree of integration and electrical characteristics are improved. The semiconductor memory device includes a channel region, a word line which extends in a first direction, a gate insulating film between the channel region and the word line, and a gate liner between the gate insulating film and the word line, where the gate liner includes silicon, where the gate liner includes a first portion and a second portion, the first portion of the gate liner is free of an impurity element, and the second portion of the gate liner includes the impurity element.

### CROSS-REFERENCE TO RELATED APPLICATION

This application claims priority from Korean Patent Application No. 10-2024-0107294, filed on Aug. 12, 2024, in the Korean Intellectual Property Office and all the benefits accruing therefrom under 35 U.S.C. § 119, the contents of which in its entirety are herein incorporated by reference.

### TECHNICAL FIELD

The present disclosure relates to a semiconductor memory device.

### BACKGROUND

There may be need to increase the degree of integration of semiconductor memory devices to satisfy demand for enhanced performance and lower price. For the semiconductor memory device, because the degree of integration may be a factor in determining the price of a product, an increased degree of integration may be particularly desirable.

For a two-dimensional or planar semiconductor memory device, the degree of integration is mainly determined by an area occupied by unit memory cells, and therefore may be affected by the level of fine pattern forming technology. However, since cost-prohibitive apparatuses may be required to miniaturize the pattern, there may be limitations in further increasing the degree of integration of the two-dimensional semiconductor memory device. Accordingly, semiconductor memory devices including a vertical channel transistor that extends in a vertical direction has been proposed.

### SUMMARY

Aspects of the present disclosure provide a semiconductor memory device having an improved degree of integration and electrical characteristics.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor memory device comprising a channel region, a word line that extends in a first direction, a gate insulating film between the channel region and the word line, and a gate liner between the gate insulating film and the word line, where the gate liner includes silicon, where the gate liner includes a first portion and a second portion, where the first portion of the gate liner is free of an impurity element, and the second portion of the gate liner includes the impurity element.

According to an aspect of the present disclosure, there is provided a semiconductor memory device comprising a bit line that extends in a second direction on a substrate, an active pattern that is on the bit line, where the active pattern includes a first side wall and a second side wall opposite to each other in the second direction, and a first face and a second face opposite to each other in a third direction that is perpendicular to the second direction, where the first face of the active pattern is electrically connected to the bit line, a word line that is on the first side wall of the active pattern and extends in a first direction that intersects the second direction and is perpendicular to the third direction, a gate insulating film that extends along the first side wall of the active patter, and is in contact with the active pattern, a gate liner that is disposed between the gate insulating film and the word line, where the gate liner includes a silicon film, a back gate electrode that is disposed on the second side wall of the active pattern and extends in the first direction, and a data storage pattern that is on the active pattern and is electrically connected to the second face of the active pattern, where the gate liner includes a first portion and a second portion, where the first portion of the gate liner is free of a first impurity element, the second portion of the gate liner includes the first impurity element, and the first impurity element includes at least one of phosphorus (P), arsenic (As), nitrogen (N) and/or germanium (Ge).

According to an aspect of the present disclosure, there is provided a semiconductor memory device comprising a peri-gate structure on a substrate, a bit line that extends in a second direction on the peri-gate structure, a shielding conductive pattern that is disposed on the peri-gate structure and includes a plurality of shielding conductive line patterns extending in the second direction and adjacent to the bit line, a first word line that is on the bit line and the shielding conductive pattern and extends in a first direction that intersects the second direction, a second word line that is on the bit line and the shielding conductive pattern, extends in the first direction, and is spaced apart from the first word line in the second direction, a back gate electrode that is between the first word line and the second word line, and extends in the first direction, a first active pattern that is on the bit line between the first word line and the back gate electrode, a second active pattern that is on the bit line between the second word line and the back gate electrode, a first gate liner that is between the first word line and the first active pattern, where the first gate liner includes silicon, a second gate liner that is between the second word line and the second active pattern, where the second gate liner includes silicon; and a data storage pattern that is electrically connected to the first active pattern and the second active pattern, where each of the first gate liner and the second gate liner comprises a first portion that is intrinsically pure, and a second portion that includes an impurity element, and where the impurity element includes at least one of phosphorus (P), arsenic (As), nitrogen (N), or germanium (Ge).

### BRIEF DESCRIPTION OF THE DRAWINGS

FIG. 1 is a layout diagram illustrating a semiconductor memory device according to some embodiments.

FIG. 2 is a cross-sectional view taken along A-A and B-B of FIG. 1.

FIG. 3 is a cross-sectional view taken along C-C and D-D of FIG. 1.

FIG. 4 is an enlarged view of a portion P of FIG. 2.

FIGS. 5 and 6 are diagrams illustrating the concentration of a first impurity element inside a first gate insulating film and a first gate liner.

FIGS. 7, 8, 9, 10, 11, 12, and 13 are diagrams illustrating a semiconductor memory device according to some embodiments.

FIGS. 14, 15, and 16 are diagrams illustrating a semiconductor memory device according to some embodiments.

FIGS. 17, 18, 19, and 20 are diagrams illustrating a semiconductor memory device according to some embodiments.

FIGS. 21 and 22 are diagrams illustrating a semiconductor memory device according to some embodiments.

FIGS. 23 and 24 are diagrams illustrating a semiconductor memory device according to some embodiments.

FIGS. 25 and 26 are diagrams illustrating a semiconductor memory device according to some embodiments.

FIGS. 27, 28, 29, and 30 are diagrams illustrating a semiconductor memory device according to some embodiments.

FIG. 31 is a layout diagram illustrating semiconductor memory device according to some embodiments.

FIG. 32 is a layout showing only a third word line and an cell active region of FIG. 31.

FIGS. 33, 34, and 35 are cross-sectional views taken along E-E, F-F, and G-G of FIG. 31.

FIG. 36 is an enlarged view illustrating the third word line, the second gate insulating film, the second gate liner, and the like of FIGS. 34 and 35.

FIGS. 37, 38, and 39 are diagrams illustrating a semiconductor memory device according to some embodiments.

FIGS. 40, 41, 42, 43, 44, 45, 46, 47, 48, 49, 50, 51, 52, 53, 54, 55, 56, 57, 58, 59, 60, 61, 62, 63, 64, 65, 66, 67, 68, and 69 are intermediate step diagrams illustrating a method for fabricating a semiconductor memory device according to some embodiments.

FIGS. 70, 71, 72, and 73 are diagrams illustrating intermediate steps of a method for fabricating a semiconductor memory device according to some embodiments.

### DETAILED DESCRIPTION OF EMBODIMENTS

It will be understood that, although the terms “first”, “second”, etc. may be used herein to describe various elements or components, these elements or components should not be limited by these terms. These terms are only used to distinguish one element or component from another element or component. The term “first,” “second,” or the like used herein may modify various elements regardless of the order and/or priority thereof, and is used only for distinguishing one element from another element, without limiting example embodiments. Therefore, a first element or component discussed below could be termed a second element or component without departing from the technical spirits of the present disclosure. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” as used herein, refers to electrical and/or physical connection between elements or components and does not preclude the presence of additional elements or components therebetween. The term “cover,” “covers,” or the like used herein may specify an element that is partially or fully, on, surrounding, or encasing another element. The term “in contact with” may be used herein to specify an element or layer that is directly adjacent to another element or layer without the presence of at least one additional element or layer therebetween. Likewise, when components or layers are referred to herein as “directly” on, or “in direct contact” or “directly connected,” no intervening components or layers are present. The term “overlap,” “overlaps,” and/or “overlapping,” when used herein may specify the position of an element as on, in contact with, and/or covering another element. Components or layers described with reference to “overlap” in a particular direction may be at least partially obstructed by one another when viewed along a line extending in the particular direction or in a plane perpendicular to the particular direction.

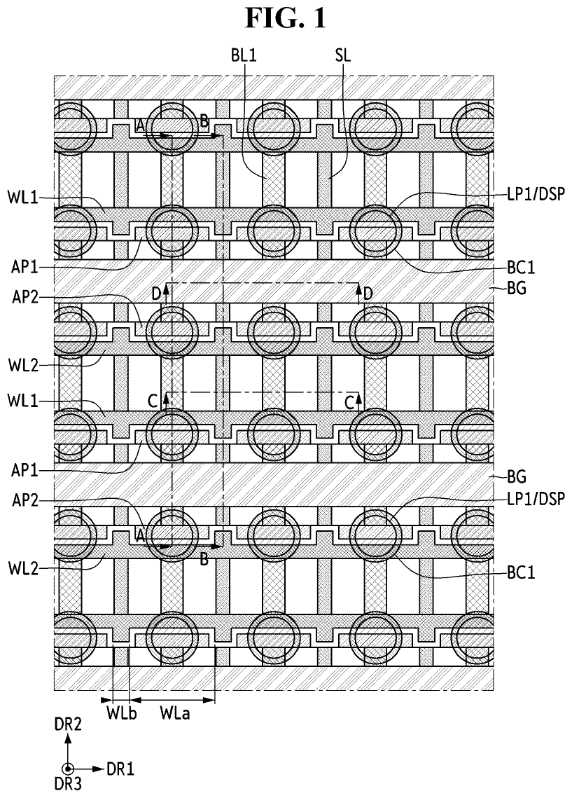

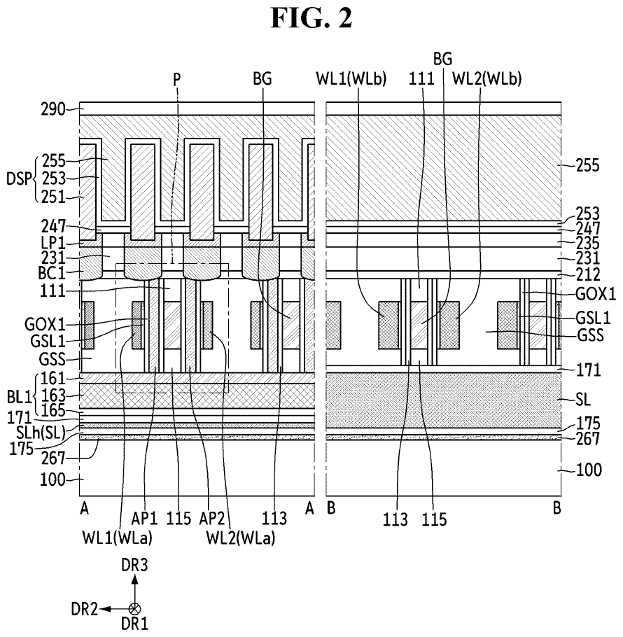

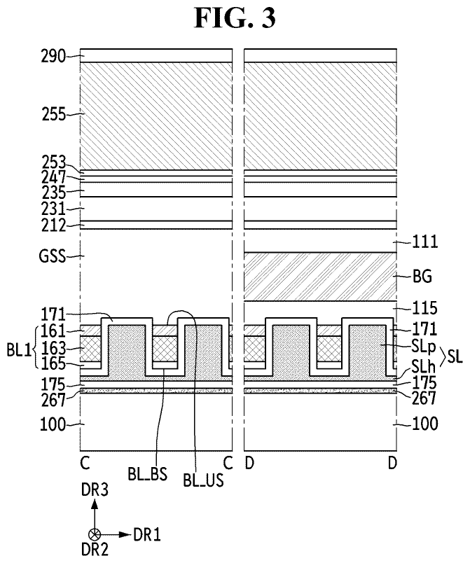

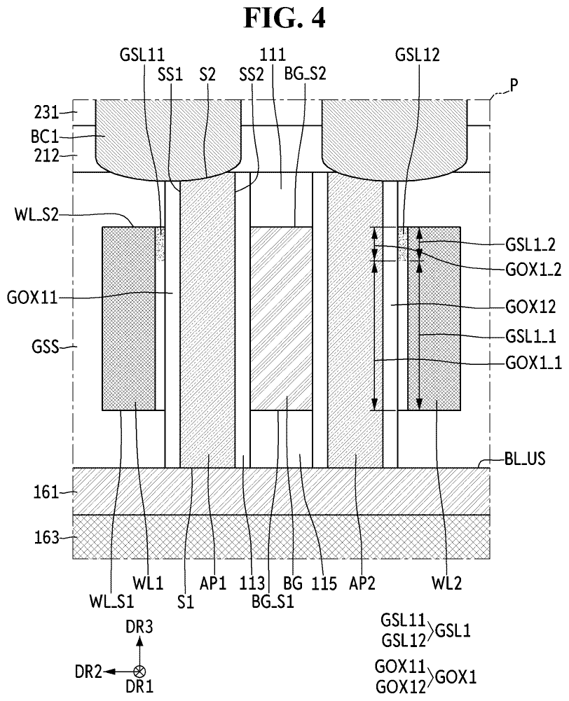

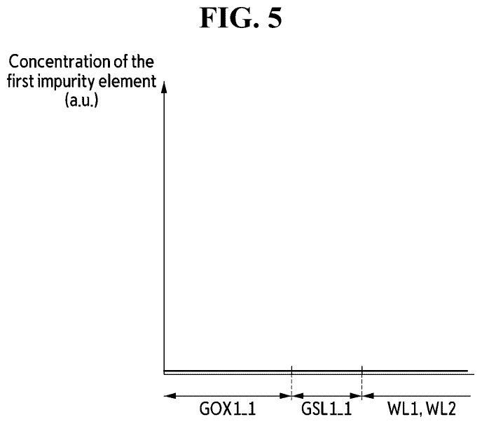

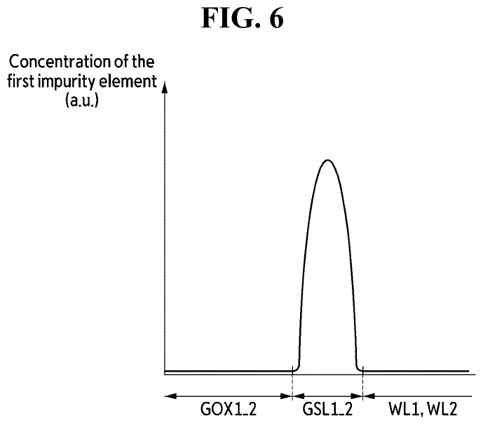

FIG. 1 is a layout diagram explaining a semiconductor memory device according to some embodiments. FIG. 2 is a cross-sectional view taken along A-A and B-B of FIG. 1. FIG. 3 is a cross-sectional view taken along C-C and D-D of FIG. 1. FIG. 4 is an enlarged view of a portion P of FIG. 2. FIGS. 5 and 6 are diagrams explaining the concentration of a first impurity element inside a first gate insulating film and a first gate liner.

A semiconductor memory device according to some embodiments of the present disclosure may include memory cells including a vertical channel transistor (VCT).

Referring to FIGS. 1-7, the semiconductor memory device according to some embodiments may include first bit lines BL1, first word lines WL1, second word lines WL2, first gate liners GSL1, back gate electrodes BG, a shielding conductive pattern SL, first active patterns AP1, second active patterns AP2, and data storage patterns DSP.

The substrate 100 may be a silicon substrate, or may include other materials, for example, but not limited to, silicon germanium, indium antimonide, lead telluride, indium arsenide, indium phosphide, gallium arsenide and/or gallium antimonide.

Although not shown, the substrate 100 may include a cell array region in which the data storage pattern DSP is disposed, and a peripheral circuit region defined around the cell array region.

A bonding insulating film 267 may be disposed on the substrate 100. The bonding insulating film 267 may be used to bond the wafer. In an example embodiment, the bonding insulating film 267 may include silicon carbonitride. As an example, the bonding insulating film 267 may include silicon oxide.

Shielding structures 171, SL, and 175 may be disposed on the substrate 100. For example, the shielding structures 171, SL, and 175 may be disposed on the bonding insulating film 267.

The shielding structures 171, SL, and 175 may include a shielding conductive pattern SL and shielding insulating films 171 and 175. For example, the shielding insulating films 171 and 175 may include a shielding insulating liner 171 and a shielding insulating capping film 175.

The shielding conductive pattern SL may include a shielding conductive plate SLh and a plurality of shielding conductive line patterns SLp. The shielding conductive plate SLh may have a flat plate shape.

Each shielding conductive line pattern SLp may extend in a second direction DR2. Each shielding conductive line pattern SLp may be adjacent to each other in a first direction DR1. The shielding conductive line pattern SLp may protrude from the shielding conductive plate SLh in a third direction DR3. The shielding conductive line pattern SLp is directly connected to the shielding conductive plate SLh.

For example, the first direction DR1 and the second direction DR2 may be horizontal directions that are horizontal to the substrate 100. The third direction DR3 may be a vertical direction that is perpendicular to the substrate 100.

The shielding conductive plate SLh and each shielding conductive line pattern SLp may extend from the cell array region to the peripheral circuit region. A part of the shielding conductive pattern SL may be disposed on the peripheral circuit region, but the embodiment is not limited thereto.

The shielding conductive pattern SL includes a conductive material. The shielding conductive pattern SL may include, for example, at least one of a conductive metal nitride, a conductive metal silicon nitride, a metal carbonitride, a conductive metal silicide, a conductive metal oxide, a two-dimensional material, and a metal.

A shielding insulating capping film 175 may be disposed on the substrate 100. For example, the shielding insulating capping film 175 may be disposed between the substrate 100 and the shielding conductive pattern SL.

The shielding insulating capping film 175 may come into contact with the shielding conductive pattern SL. In the semiconductor memory device according to some embodiments, the shielding insulating capping film 175 may come into contact with the shielding conductive plate SLh.

A shielding insulating liner 171 may be disposed on the shielding conductive pattern SL. The shielding insulating liner 171 may be disposed between the first bit line BL1 and the substrate 100. The shielding insulating liner 171 may extend along the profiles of the shielding conductive plate SLh and the shielding conductive line pattern SLp.

Each of the shielding insulating liner 171 and the shielding insulating capping film 175 may be formed of an insulating material. When the shielding insulating liner 171 and the shielding insulating capping film 175 include the same material, a boundary between the shielding insulating liner 171 and the shielding insulating capping film 175 may not be distinguished (i.e., may not be visible or recognizable).

Because the shielding structures (e.g. shielding insulating liner 171, shielding conductive pattern SL, and shielding capping film 175) are disposed between the first bit lines BL1 adjacent to each other in the first direction DR1, a coupling noise between the first bit lines BL1 may be reduced.

The semiconductor memory device according to some embodiments may not include the shielding conductive pattern SL.

The first bit lines BL1 may be disposed on the substrate 100. For example, the first bit lines BL1 may be disposed on the bonding insulating film 267.

The first bit line BL1 may extend long in the second direction DR2. Adjacent first bit lines BL1 may be spaced apart from each other in the first direction DR1. The first bit line BL1 includes a long side wall extending in the second direction DR2, and a short side wall extending in the first direction DR1.

The first bit line BL1 may be disposed on the shielding conductive pattern SL. The first bit line BL1 may be disposed on the shielding conductive plate SLh.

The first bit line BL1 may be disposed to be adjacent to the shielding conductive line pattern SLp. The first bit line BL1 may be disposed to be adjacent to the shielding conductive line pattern SLp in the first direction DR1. In other words, the shielding conductive line pattern SLp may extend in the second direction DR2 along the long side wall of the first bit line BL1.

The first bit line BL1 may be disposed between the shielding conductive line patterns SLp adjacent to each other in the first direction DR1. The first bit line BL1 may be disposed on the shielding insulating liner 171. For example, the shielding insulating liner 171 may come into contact with the first bit line BL1.

Although not shown, each first bit line BL1 may extend from the cell array region to the peripheral circuit region. A part of each first bit line BL1 may be disposed on the peripheral circuit region.

The first bit line BL1 may include an upper face BL_US and a bottom face BL_BS that are opposite to each other in the third direction DR3. The upper face BL_US of the first bit line may face a first active pattern AP1 and a second active pattern AP2, which will be described below.

In the semiconductor memory device according to some embodiments, the shielding conductive pattern SL may be disposed on the bottom face BL_BS of the first bit line. For example, the shielding conductive plate SLh may be disposed on the bottom face BL_BS of the first bit line.

Each first bit line BL1 may include a semiconductor pattern 161, a metal pattern 163, and a bit line mask pattern 165 that are stacked sequentially. As an example, the first bit line BL1 may include one of the semiconductor pattern 161 and the metal pattern 163. As an example, the first bit line BL1 may not include the bit line mask pattern 165.

The first bit line BL1 may include a conductive bit line. The conductive bit line includes a film made of a conductive material among the first bit lines BL1. The conductive bit line may include the semiconductor pattern 161 and the metal pattern 163.

The semiconductor pattern 161 may include a conductive semiconductor material. The conductive semiconductor material may be, for example, a semiconductor material doped with impurities. The semiconductor pattern 161 may include at least one of poly silicon, poly silicon germanium, poly germanium, amorphous silicon, amorphous silicon germanium, and amorphous germanium.

The metal pattern 163 may include a conductive material including a metal. The metal pattern 163 may include, for example, at least one of a conductive metal nitride, a conductive metal silicon nitride, a metal carbonitride, a conductive metal silicide, a conductive metal oxide, a two-dimensional material, and a metal. In the semiconductor memory device according to some embodiments, the two-dimensional material may be a metallic material and/or a semiconductor material. The two-dimensional material may include a 2D allotrope or a 2D compound, and may include, but not limited to, at least one of graphene, molybdenum disulfide (MoS₂), molybdenum diselenide (MoSe₂), tungsten diselenide (WSc₂), and tungsten disulfide (WS₂). Since the above-mentioned two-dimensional materials are only listed as an example, the two-dimensional materials that may be included in the semiconductor memory device of the present disclosure are not limited by the above-mentioned materials.

The bit line mask pattern 165 may include an insulating material. The bit line mask pattern 165 may include, but is not limited to, silicon nitride, silicon oxynitride or the like.

The first active patterns AP1 and the second active patterns AP2 may be disposed on each first bit line BL1. The first active patterns AP1 and the second active patterns AP2 may be disposed alternately along the second direction DR2.

The first active patterns AP1 may be spaced apart from each other in the first direction DR1. The first active patterns AP1 may be spaced apart at regular intervals. The second active patterns AP2 may be spaced apart from each other in the first direction DR1. The second active patterns AP2 may be spaced apart at regular intervals. The first active patterns AP1 may be spaced apart from the second active patterns AP2 in the second direction DR2. The first active patterns AP1 and the second active patterns AP2 may be arranged two-dimensionally along the first direction DR1 and the second direction DR2 that intersect each other.

Each of the first active pattern AP1 and the second active pattern AP2 may be a channel region. For example, each of the first active pattern AP1 and the second active pattern AP2 may be made of a single crystal semiconductor material. For example, each of the first active pattern AP1 and the second active pattern AP2 may be made of a single crystal semiconductor material. Each of the first active pattern AP1 and the second active pattern AP2 may be a silicon active pattern.

Each of the first active pattern AP1 and the second active pattern AP2 may have a length in the first direction DR1, a width in the second direction DR2, and a height in the third direction DR3. Each of the first active pattern AP1 and the second active pattern AP2 may have a substantially uniform width. That is, each of the first active pattern AP1 and the second active pattern AP2 may have substantially the same width on the first and second faces S1 and S2. Furthermore, the width of the first active pattern AP1 may be equal to the width of the second active pattern AP2.

A width of the first active pattern AP1 and a width of the second active pattern AP2 may range from several nm to several tens of nm. For example, the width of the first active pattern AP1 and the width of the second active pattern AP2 may be, but is not limited to, 1 nm to 30 nm, and may be 1 nm to 10 nm. A length of each of the first and second active patterns AP1 and AP2 may be greater than a line width of the first bit line BL1. In other words, the length of each of the first and second active patterns AP1 and AP2 may be greater than the width of the first bit line BL1 in the first direction DR1.

In FIG. 4, each of the first active pattern AP1 and the second active pattern AP2 includes a first face S1 and a second face S2 that are opposite to each other in the third direction DR3. For example, the first face S1 of the first and second active patterns AP1 and AP2 may look at the first bit line BL1. The second face S2 of the first and second active patterns AP1 and AP2 may look at the first contact pattern BC1.

The first face S1 of the first and second active patterns AP1 and AP2 are connected to the first bit line BL1. For example, the first face S1 of the first and second active patterns AP1 and AP2 may be connected to the semiconductor pattern 161 of the first bit line BL1. When the semiconductor pattern 161 is omitted, the first face S1 of the first and second active patterns AP1 and AP2 may be connected to the metal pattern 163. The second face S2 of the first and second active patterns AP1 and AP2 may be connected to the first contact pattern BC1.

Each of the first active pattern AP1 and the second active pattern AP2 may include a first side wall SS1 and a second side wall SS2 that are opposite to each other in the second direction DR2. The second side wall SS2 of the first active pattern AP1 may face the first side wall SS1 of the second active pattern AP2.

The first side wall SS1 of the first active pattern AP1 may be adjacent to a first word line WL1. The second side wall SS2 of the second active pattern AP2 may be adjacent to a second word line WL2.

Although not shown, as an example, each of the first and second active patterns AP1 and AP2 may include a first dopant portion adjacent to the first bit line BL1, and a second dopant portion adjacent to the first contact pattern BC1. Each of the first active pattern AP1 and the second active pattern AP2 may include a channel portion between the first dopant portion and the second dopant portion. The first dopant portion and the second dopant portion are regions in which a dopant is doped inside the first active pattern AP1 and the second active pattern AP2. In some embodiments, each of the first active pattern AP1 and the second active pattern AP2 may not include at least one of the first dopant portion and the second dopant portion.

At the time of operation of the semiconductor memory device, the channel portion of the first and second active patterns AP1 and AP2 may be controlled by the first and second word lines WL1 and WL2 and the back gate electrodes BG. Since the first and second active patterns AP1 and AP2 are made of a single crystal semiconductor material, leakage current characteristics of the semiconductor memory device may be improved.

The back gate electrodes BG may be disposed on the first bit line BL1 and the shielding conductive pattern SL. The back gate electrodes BG may be spaced apart from each other in the second direction DR2. The back gate electrodes BG may be spaced apart at regular intervals. Each back gate electrode BG may extend in the first direction DR1 across the first bit line BL1.

Each back gate electrode BG may be disposed between the first active pattern AP1 and the second active pattern AP2 that are adjacent to each other in the second direction DR2. In other words, the first active pattern AP1 may be disposed on one side of each back gate electrode BG, and the second active pattern AP2 may be disposed on the other side of each back gate electrode BG. Each back gate electrode BG may be disposed between the second side wall SS2 of the first active pattern AP1 and the first side wall SS1 of the second active pattern AP2. A height of the back gate electrode BG in the third direction DR3 may be smaller than heights of the first and second active patterns AP1 and AP2.

The first active pattern AP1 may be disposed between the first word line WL1 and the back gate electrode BG. The second active pattern AP2 may be disposed between the second word line WL2 and the back gate electrode BG. A pair of word lines including a first word line WL1 and a second word line WL2 may be disposed between the back gate electrodes BG adjacent to each other in the second direction DR2.

The back gate electrode BG may include a first face BG_S1 and a second face BG_S2 that are opposite to each other in the third direction DR3. The first face BG_S1 of the back gate electrode is closer to the first bit line BL1 than the second face BG_S2 of the back gate electrode. The first face BG_S1 of the back gate electrode may look at the first bit line BL1.

The back gate electrode BG includes a conductive material, and may include, for example, at least one of a conductive semiconductor material, a conductive metal nitride, a conductive metal silicon nitride, a metal carbonitride, a conductive metal silicide, a two-dimensional material, and a metal.

In the semiconductor memory device according to some embodiments, the back gate electrode BG may include a first metal element. For example, the first metal element may be titanium (Ti). The back gate electrode BG may include titanium nitride (TIN).

A voltage is applied to the back gate electrode BG at the time of operation of the semiconductor memory device, and a threshold voltage of the vertical channel transistor may be adjusted. Because the threshold voltage of the vertical channel transistor is adjusted, the leakage current characteristics may be prevented from deteriorating.

A back gate separation pattern 111 may be disposed between the first active pattern AP1 and the second active pattern AP2 that are adjacent to each other in the second direction DR2. The back gate separation pattern 111 may extend in the first direction DR1 along with the back gate electrode BG. The back gate separation pattern 111 may be disposed on the second face BG_S2 of the back gate electrode.

The back gate separation pattern 111 may be formed of an insulating material. The back gate separation pattern 111 may include, for example, but is not limited to, a silicon oxide film, a silicon oxynitride film or a silicon nitride film.

A back gate insulating film 113 may be disposed between the back gate electrode BG and the first active pattern AP1, and between the back gate electrode BG and the second active pattern AP2. The back gate insulating film 113 may be disposed between the back gate separation pattern 111 and the first active pattern AP1, and between the back gate separation pattern 111 and the second active pattern AP2.

The back gate insulating film 113 may extend along the second side wall SS2 of the first active pattern AP1 and the first side wall SS1 of the second active pattern AP2. The back gate insulating film 113 may come into contact with the first active pattern AP1 and the second active pattern AP2.

The back gate insulating film 113 may be formed of an insulating material. The back gate insulating film 113 may include, for example, but is not limited to, a silicon oxide.

A back gate capping pattern 115 may be disposed between the first bit line BL1 and the back gate electrode BG. The back gate capping pattern 115 may be disposed between the first active pattern AP1 and the second active pattern AP2 that are adjacent to each other in the second direction DR2. The back gate capping pattern 115 may extend in the first direction DR1 along with the back gate electrode BG. The back gate capping pattern 115 may be disposed on the first face BG_S1 of the back gate electrode. A thickness of the back gate capping pattern 115 between the first bit lines BL1 may be different from the thickness of the back gate capping pattern 115 on the upper face BL_US of the first bit line, but is not limited thereto.

The back gate capping pattern 115 may be made of an insulating material. The back gate capping pattern 115 may include, for example, but is not limited to, at least one of a silicon oxide film, a silicon oxynitride film, and a silicon nitride film.

The first word line WL1 and the second word line WL2 may be disposed on the first bit line BL1 and the shielding conductive pattern SL. Each of the first word line WL1 and the second word line WL2 may extend in the first direction DR1. The first word line WL1 and the second word line WL2 may be arranged alternately in the second direction DR2.

The first word line WL1 may be disposed on the first side walls SS1 of the first active patterns AP1. The second word line WL2 may be disposed on the second side walls SS2 of the second active patterns AP2. The first active patterns AP1 and the second active patterns AP2 may be disposed between the first word line WL1 and the second word line WL2 that are adjacent to each other in the second direction DR2.

In the semiconductor memory device according to some embodiments, the first word line WL1 and the second word line WL2 may be spaced apart from the first bit line BL1 and the first contact pattern BC1 in the third direction DR3. The first word line WL1 and the second word line WL2 may be located between the first bit line BL1 and the first contact pattern BC1.

Each of the first word line WL1 and the second word line WL2 may have a width in the second direction DR2. As an example, the width of the first word line WL1 and the width of the second word line WL2 on the first bit line BL1 may be different from the width of the first word line WL1 and the width of the second word line WL2 on the shielding conductive line pattern SLp.

For example, each of the first word line WL1 and the second word line WL2, respectively, may include a first portion WLa of the word line, and a second portion WLb of the word line. A width of the first portion WLa of the word line in the second direction DR2 may be smaller than a width of the second portion WLb of the word line in the second direction DR2. As an example, the first portion WLa of the word line may be disposed on the first bit line BL1. The second portion WLb of the word line may be disposed on the shielding conductive line SL.

Each of the first word line WL1 and the second word line WL2 may include the first portion WLa of the word line and the second portion WLb of the word line that are disposed alternately along the first direction DR1. On the first word line WL1, each first active pattern AP1 may be disposed between the second portions WLb of the word lines that are adjacent to each other in the first direction DR1. On the second word line WL2, each second active pattern AP2 may be disposed between the second portions WLb of the word lines that are adjacent in the first direction DR1.

In some embodiments, the width of the first portion WLa of the word line in the second direction DR2 may be identical to the width of the second portion WLb of the word line in the second direction DR2. In other words, the width of the first word line WL1 and the width of the second word line WL2 on the first bit line BL1 may be identical to the width of the first word line WL1 and the width of the second word line WL2 on the shielding conductive line pattern SLp. In such a case, a first gate insulating pattern GOX1, which will be described below, may fill a space between the first active patterns AP1 adjacent to each other in the first direction DR1 and a space between the second active patterns AP2 adjacent to each other in the first direction DR1.

The first word line WL1 and the second word line WL2 may include a first face WL_S1 and a second face WL_S2 that are opposite to each other in the third direction DR3. The first faces WL_S1 of the first and second word lines are closer to the first bit line BL1 than the second sides WL_S2 of the first and second word lines. The first faces WL_S1 of the first and second word lines look at the first bit line BL1. When the first face WL_S1 of the first and second word lines look at the substrate 100, the second face WL_S2 of the first and second word lines may be the upper faces of the first and second word lines WL1 and WL2. When the second face WL_S2 of the first and second word lines looks at the substrate 100, the first face WL_S1 of the first and second word lines may be the upper face of the first and second word lines WL1 and WL2.

The first word line WL1 will be explained as an example. As an example, a height of the first word line WL1 in the third direction DR3 may be identical to a height of the back gate electrode BG in the third direction DR3. As an example, the height of the first word line WL1 in the third direction DR3 may be greater than the height of the back gate electrode BG in the third direction DR3. As an example, the height of the first word line WL1 in the third direction DR3 may be smaller than the height of the back gate electrode BG in the third direction DR3.

Furthermore, as an example, the height of the first face WL_S1 of the first word line may be identical to the height of the first face BG_S1 of the back gate electrode, based on the upper face BL_US of the first bit line. As an example, the first face WL_S1 of the first word line may be higher than the first face BG_S1 of the back gate electrode. As an example, the first face WL_S1 of the first word line may be lower than the first face BG_S1 of the back gate electrode.

In addition, as an example, the height of the second face WL_S2 of the first word line may be identical to the height of the second face BG_S2 of the back gate electrode, based on the upper face BL_US of the first bit line. As an example, the second face WL_S2 of the first word line may be higher than the second face BG_S2 of the back gate electrode. As an example, the second face WL_S2 of the first word line may be lower than the second face BG_S2 of the back gate electrode.

The first face WL_S1 of the first and second word lines WL1 and WL2 may be, but are not limited to, a plane. The second face WL_S2 of the first and second word lines WL1 and WL2 may be, but are not limited to, a plane. Although the first face BG_S1 of the back gate electrode and the second face BG_S2 of the back gate electrode are shown a being a plane or planar surface, example embodiments are not limited thereto.

The first word line WL1 and the second word line WL2 may include a conductive material. The first word line WL1 and the second word line WL2 may include at least one of, for example, a conductive semiconductor material, a conductive metal nitride, a conductive metal silicon nitride, a conductive metal carbonitride, a conductive metal silicide, a conductive metal oxide, a two-dimensional material, and a metal.

In the semiconductor memory device according to some embodiments, the first word line WL1 and the second word line WL2 may include a second metal element. For example, the second metal element may be titanium (Ti). The first word line WL1 and the second word line WL2 may include titanium nitride (TiN).

First gate insulating films GOX1 may be disposed between the first word line WL1 and the first active pattern AP1, and between the second word line WL2 and the second active pattern AP2. The first gate insulating films GOX1 may extend in the first direction DR1 alongside the first word line WL1 and the second word line WL2.

The first gate insulating film GOX1 may include a first sub-gate insulating film GOX11 and a second sub-gate insulating film GOX12. The first sub-gate insulating film GOX11 may be disposed between the first word line WL1 and the first active pattern AP1. The second sub-gate insulating film GOX12 may be disposed between the second word line WL2 and the second active pattern AP1.

A first sub-gate insulating film GOX11 may extend along the first side wall SS1 of the first active pattern AP1, and a second sub-gate insulating film GOX12 may extend along the second side wall SS2 of the second active pattern AP2. The first sub-gate insulating film GOX11 may come into contact with the first active pattern AP1, and the second sub-gate insulating film GOX12 may come into contact with the second active pattern AP2.

The first sub-gate insulating film GOX11 may not extend along the first face WL_S1 of the first word line WL1, and the second sub-gate insulating film GOX12 may not extend along the first face WL_S1 of the second word line WL2. The first sub-gate insulating film GOX11 may not extend along the second face WL_S2 of the first word line WL1, and the second sub-gate insulating film GOX12 may not extend along the second face WL_S2 of the second word line WL2.

The first gate insulating film GOX1 may be made of an insulating material. The first gate insulating film GOX1 may include, for example, but is not limited to, silicon oxide.

A first gate liner GSL1 may be disposed between the first word line WL1 and the first active pattern AP1, and between the second word line WL2 and the second active pattern AP2. The first gate liner GSL1 may be disposed between the first word line WL1 and the first gate insulating film GOX1, and between the second word line WL2 and the first gate insulating film GOX1.

The first gate liner GSL1 does not extend along the first face WL_S1 of the first and second word lines WL1 and WL2. The first gate liner GSL1 may not extend along the second face WL_S2 of the first and second word lines WL1 and WL2.

The first gate liner GSL1 may extend along a boundary between the first word line WL1 and the first gate insulating film GOX1, and a boundary between the second word line WL2 and the first gate insulating film GOX1. For example, the first gate liner GSL1 may come in contact with the first gate insulating film GOX1.

The first gate liner GSL1 may include a first sub-gate liner GSL11 and a second sub-gate liner GSL12. The first sub-gate liner GSL11 may extend along the boundary between the first word line WL1 and the first gate insulating film GOX1. The second sub-gate liner GSL12 may extend along the boundary between the second word line WL2 and the first gate insulating film GOX1. The first sub-gate liner GSL11 and the second sub-gate liner GSL12 may come in contact with the first gate insulating film GOX1.

The first gate liner GSL1 may include silicon. For example, the first gate liner GSL1 may include a silicon film. The first gate liner GSL1 may be a gate silicon liner.

The first gate liner GSL1 may include a first portion GSL1_1 and a second portion GSL1_2. The second portion GSL1_2 of the first gate liner may include a doped first impurity element. The first portion GSL1_1 of the first gate liner may not include the first impurity element, i.e., may be free of the first impurity element. In some embodiments, the first portion GSL1_1 of the first gate liner may be undoped (i.e., not intentionally doped) or intrinsically pure. The first impurity element may include, for example, at least one of phosphorus (P), arsenic (As), nitrogen (N), and germanium (Ge).

The first gate insulating film GOX1 may include a first portion GOX1_1 and a second portion GOX1_2. The first portion GOX1_1 of the first gate insulating film may overlap the first portion GSL1_1 of the first gate liner in the second direction DR2. The second portion GOX1_2 of the first gate insulating film may overlap the second portion GSL1_2 of the first gate liner in the second direction DR2.

FIG. 5 is a diagram showing a change in concentration (/cm³) of the first impurity element along the second direction (+DR2 or −DR2) in a partial region of the semiconductor device. Specifically, FIG. 5 is a diagram showing the change in concentration (/cm³) of the first impurity element in the first portion GOX1_1 of the first gate insulating film, the first portion GSL1_1 of the first gate liner, and the first word line WL1 or the second word line WL2. The first portion GOX1_1 of the first gate insulating film and the first portion GSL1_1 of the first gate liner may not include the first impurity element. The concentration of the first impurity element may be 0 in the first portion GOX1_1 of the first gate insulating film and the first portion GSL1_1 of the first gate liner. Here, the concentration of the first impurity element being “0” may mean that the impurity element does not exist inside the film or that an amount less than a detection limit of the measurement device exists. In some embodiments, the first portion GOX1_1 of the first gate insulating film and the first portion GSL1_1 of the first gate liner may be undoped or intrinsically pure.

FIG. 6 is a diagram showing a concentration change of the first impurity element in the second portion GOX1_2 of the first gate insulating film and the second portion GSL1_2 of the first gate liner. The second portion GOX1_2 of the first gate insulating film may not include the first impurity element. In the portion that overlaps the second portion GSL1_2 of the first gate liner in the second direction DR2, the first and second word lines WL1 and WL2 may not include the first impurity element.

The second portion GOX1_2 of the first gate insulating film may include the first impurity element in the portion that forms a boundary with the first gate liner GSL1. The first and second word lines WL1 and WL2 may include the first impurity element in the portion that forms a boundary with the second portion GSL1_2 of the first gate liner. In such a case, the concentration of the first impurity element may decrease as it goes away from the second portion GSL1_2 of the first gate liner.

Because a dipole due to the first impurity element between the first gate liner GSL1 and the first gate insulating film GOX1 is formed, a work function of the gate electrode of the transistor may be adjusted. Because only a part of the first gate liner GSL1 is doped with the impurity, the gate electrode of the transistor may have a multi-work function structure. A gate induced drain leakage (GIDL) characteristic of the transistor may be improved, accordingly.

While the first impurity element is being doped into a part of the first gate liner GSL1, a part of the second metal element included in the first word line WL1 and the second word line WL2 may fly or may be scattered toward the first gate insulating film GOX1. Defects may occur at a boundary between the first gate insulating film GOX1 and the active patterns AP1 and AP2 due to the second metal element that flies toward the first gate insulating film GOX1. The defects that occur at the boundary between the first gate insulating film GOX1 and the active patterns AP1 and AP2 may serve as a trap site that captures charges when the transistor operates.

However, the first gate liner GSL1 may reduce the flying speed of the second metal element included in the first word line WL1 and the second word line WL2. That is, the first gate liner GSL1 may serve as a buffer that reduces the kinetic energy of the second metal element. This may prevent or reduce an occurrence of defects at the boundary between the first gate insulating film GOX1 and the active patterns AP1 and AP2. The performance and reliability of the semiconductor memory device can be improved, accordingly.

In the semiconductor memory device according to some embodiments, the second portion GSL1_2 of the first gate liner may be closer to the first contact pattern BC1 than the first portion GSL1_1 of the first gate liner. That is, the second portion GSL1_2 of the first gate liner may be closer to the data storage pattern DSP than the first portion GSL1_1 of the first gate liner.

The gate separation pattern GSS may be disposed on the first bit line BL1. The gate separation pattern GSS may be disposed between the first word line WL1 and the second word line WL2 that are adjacent to each other in the second direction DR2. The first word line WL1 and the second word line WL2 may be separated by the gate separation pattern GSS. The gate separation pattern GSS may extend in the first direction DR1 between the first word line WL1 and the second word line WL2.

The first word line WL1 may be disposed between the gate separation pattern GSS and the first active pattern AP1. The gate separation pattern GSS may be disposed on the first side wall SS1 of the first active pattern AP1. The second word line WL2 may be disposed between the gate separation pattern GSS and the second active pattern AP2. The gate separation pattern GSS may be disposed on the second side wall SS2 of the second active pattern AP2.

The gate separation pattern GSS may be made of an insulating material. Although the gate separation pattern GSS is shown as being a single film, this is only for convenience of explanation, and example embodiments are not limited thereto. The gate separation pattern GSS may include a plurality of insulating films.

The first contact patterns BC1 may penetrate a contact interlayer insulating film 231 and a contact etching stop film 212. The first contact patterns BC1 may each be connected to the first active pattern AP1 or the second active pattern AP2. The first contact patterns BC1 may each be connected to the second face S2 of the corresponding first and second active patterns AP1 and AP2. Each of the first contact patterns BC1 may have various shapes such as a circle, an ellipse, a rectangle, a square, a rhombus or a hexagon from a planar viewpoint, i.e., in plan view.

The first contact pattern BC1 may include a conductive material. The first contact pattern BC1 may include, for example, at least one of a doped polysilicon, a conductive metal nitride, a conductive metal silicon nitride, a metal carbonitride, a conductive metal silicide, a conductive metal oxide, a two-dimensional material, and a metal

The contact etching stop film 212 may be disposed on the gate separation pattern GSS and the back gate separation pattern 111. Each of the contact interlayer insulating film 231 and the contact etching stop film 212 may be formed of an insulating material.

The first landing pads LP1 may be disposed on one of the first contact patterns BC1. The first landing pads LP1 may have various shapes such as a circle, an ellipse, a rectangle, a square, a rhombus, and a hexagon from a planar viewpoint.

Pad separation insulating patterns 235 may be disposed between the first landing pads LP1. The first landing pads LP1 may be arranged in the form of a matrix along the first direction DR1 and the second direction DR2 from the planar viewpoint. The upper face of the first landing pad LP1 may be, but is not limited to, substantially coplanar with the upper face of the pad separation insulating pattern 235.

The first landing pad LP1 includes a conductive material, and may include, for example, at least one of a doped polysilicon, a conductive metal nitride, a conductive metal silicon nitride, a metal carbonitride, a conductive metal silicide, a conductive metal oxide, a 2D material, and a metal.

The semiconductor memory device according to some embodiments may not include the first landing pad LP1.

Data storage patterns DSP may be disposed on the landing pads LP, respectively. The data storage patterns DSP may be electrically connected to each of the first and second active patterns AP1 and AP2. The data storage patterns DSP may be arranged in the form of a matrix along the first direction DR1 and the second direction DR2, as shown in FIG. 1. The data storage patterns DSP may completely or partially overlap the landing pads LP in the third direction DR3. The data storage patterns DSP may come into contact with all or part of the upper face of the first landing pads LP1.

As an example, the data storage patterns DSP may be a capacitor. The data storage patterns DSP may include a capacitor dielectric film 253 interposed between the storage electrodes 251 and the plate electrode 255. For example, the storage electrode 251 may come into contact with the first landing pad LP1. The storage electrode 251 may have various shapes such as a circle, an ellipse, a rectangle, a square, a rhombus, and a hexagon from the planar viewpoint.

The data storage patterns DSP may come into contact with all or part of the upper face of the first landing pad LP1. The storage electrodes 251 may penetrate the upper etching stop film 247. The upper etching stop film 247 may be formed of an insulating material. Although a part of the storage electrode 251 is shown to enter the first landing pad LP1, the example embodiments are not limited thereto.

Each of the storage electrode 251 and the plate electrode 255 may include, for example, at least one of a conductive semiconductor material, a conductive metal nitride, a conductive metal silicon nitride, a metal carbonitride, a conductive metal silicide, a conductive metal oxide, and a metal. The capacitor dielectric film 253 may include at least one of a ferroelectric material, an antiferroelectric material, and a paraelectric material. For example, the capacitor dielectric film 253 may include one of the ferroelectric material, the antiferroelectric material, the paraelectric material, a combination of the ferroelectric and antiferroelectric materials, a combination of the ferroelectric and paraelectric materials, a combination of paraelectric and antiferroelectric materials, and a combination of the ferroelectric material, the antiferroelectric material and the paraelectric material.

In contrast, the data storage patterns DSP may be variable resistance patterns that may be switched into two resistance statuses by electrical pulses applied to the memory element. For example, the data storage patterns DSP may include a phase-change material whose crystal status changes depending on the amount of current, perovskite compounds, transition metal oxide, magnetic materials, ferromagnetic materials or antiferromagnetic materials

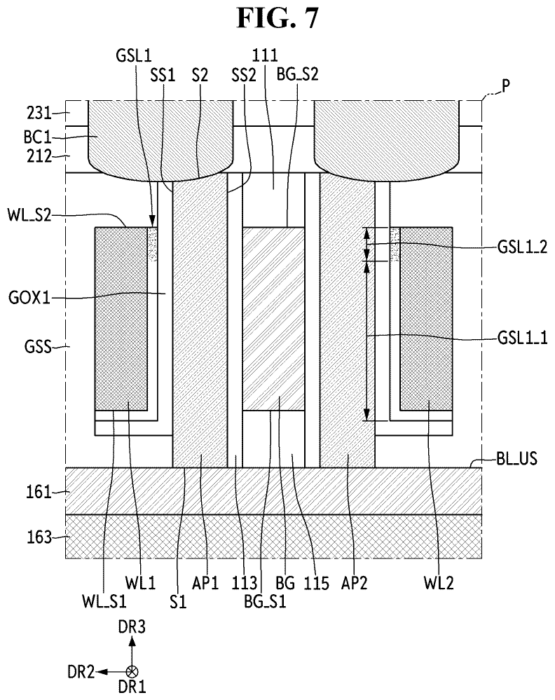

FIGS. 7 to 13 are diagrams for explaining a semiconductor memory device according to some embodiments, respectively. For convenience of explanation, points different from those described using FIGS. 1 to 6 will be mainly explained.

Referring to FIG. 7, in the semiconductor memory device according to some embodiments, the first gate insulating film GOX1 may extend along the first face WL_S1 of the first and second word lines WL1 and WL2.

The first gate liner GSL1 may extend along the first face WL_S1 of the first and second word lines WL1 and WL2.

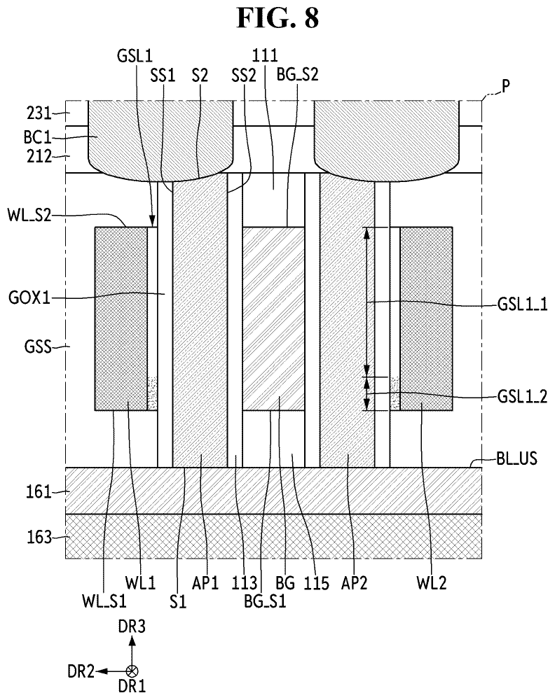

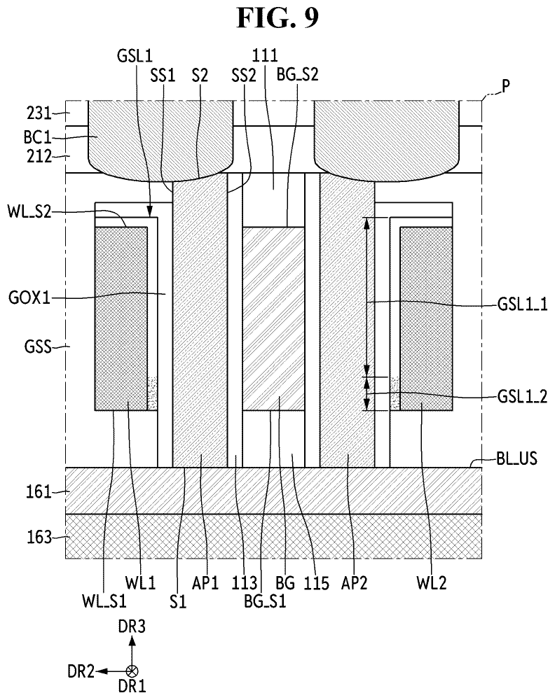

Referring to FIGS. 8 and 9, in the semiconductor memory device according to some embodiments, the first portion GSL1_1 of the first gate liner may be closer to the first contact pattern BC1 than the second portion GSL1_2 of the first gate liner.

In other words, the second portion GSL1_2 of the first gate liner may be closer to the first bit line BL1 than the first portion GSL1_1 of the first gate liner.

The first gate insulating film GOX1 and the first gate metal oxide film GMOX1 may not extend along the first face WL_S1 of the first and second word lines WL1 and WL2.

In FIG. 8, the first gate insulating film GOX1 and the first gate liner GSL1 may not extend along the second face WL_S2 of the first and second word lines WL1 and WL2. The first gate insulating film GOX1 and the first gate liner GSL1 may not include a portion that covers the first face WL_S1 of the first and second word lines WL1 and WL2.

In FIG. 9, the first gate insulating film GOX1 and the first gate liner GSL1 may extend along the second face WL_S2 of the first and second word lines WL1 and WL2, respectively.

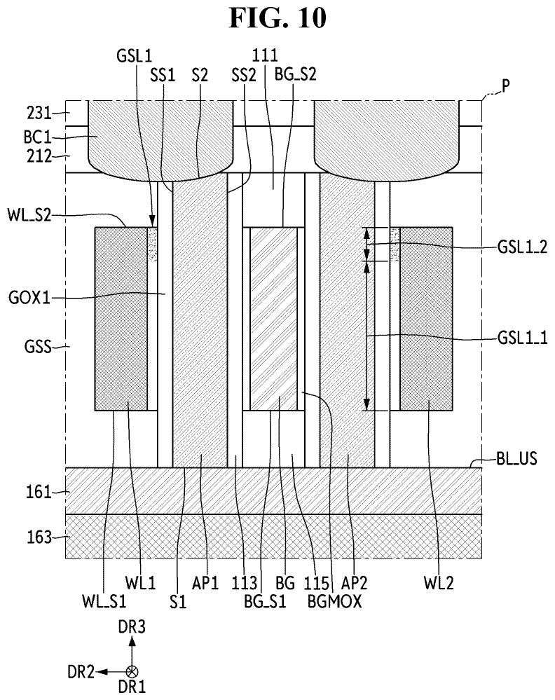

Referring to FIG. 10, the semiconductor memory device according to some embodiments may further include a back gate metal oxide film BGMOX disposed between the back gate electrode BG and the back gate insulating film 113.

The back gate metal oxide film BGMOX may be disposed between the back gate electrode BG and the first active pattern AP1, and between the back gate electrode BG and the second active pattern AP2.

The back gate metal oxide film BGMOX may extend along a side wall of the back gate electrode BG extending in the third direction DR3. The back gate metal oxide film BGMOX may extend along the boundary between the back gate electrode BG and the back gate insulating film 113. For example, the back gate metal oxide film BGMOX may come into contact with the back gate electrode BG and the back gate insulating film 113.

For example, the back gate metal oxide film BGMOX may include a first metal oxide. The first metal oxide may be an oxide of a first metal element included in the back gate electrode BG. When the back gate electrode BG includes titanium nitride (TiN), the first metal oxide may be titanium oxide. The back gate metal oxide film BGMOX may include titanium oxide.

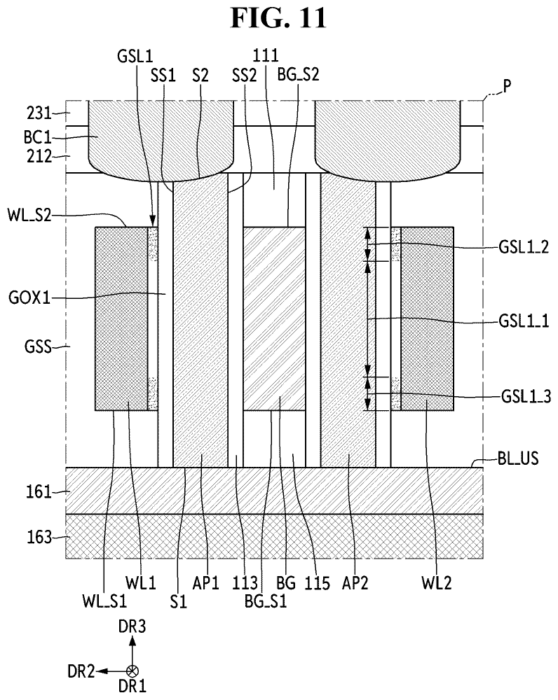

Referring to FIG. 11, in the semiconductor memory device according to some embodiments, the first gate liner GSL1 may further include a third portion GSL1_3.

The first portion GSL1_1 of the first gate liner may be disposed between the second portion GSL1_2 of the first gate liner and the third portion GSL1_3 of the first gate liner. The third portion GSL1_3 of the first gate liner may be closer to the first bit line BL1 than the first portion GSL1_1 of the first gate liner.

The third portion GSL1_3 of the first gate liner may include a doped first impurity element. As an example, the first impurity element included in the third portion GSL1_3 of the first gate liner may be identical to the first impurity element included in the second portion GSL1_2 of the first gate liner. As an example, the first impurity element included in the third portion GSL1_3 of the first gate liner may be different from the first impurity element included in the second portion GSL1_2 of the first gate liner.

The first gate insulating film GOX1 may include a third portion that overlaps the third portion GSL1_3 of the first gate liner in the second direction DR2. The first portion (GOX1_1 of FIG. 4) of the first gate insulating film may be disposed between the second portion (GOX1_2 of FIG. 4) of the first gate insulating film and the third portion of the first gate insulating film GOX1.

As an example, the third portion of the first gate insulating film GOX1 may include the first impurity element at a portion that forms a boundary with the third portion GSL1_3 of the first gate liner. As an example, the third portion of the first gate insulating film GOX1 may not include the first impurity element at a portion that forms the boundary with the third portion GSL1_3 of the first gate liner.

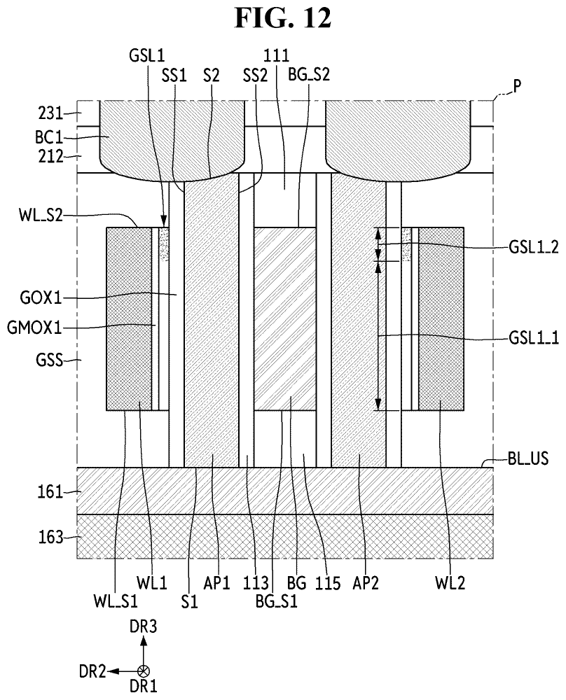

Referring to FIG. 12, the semiconductor memory device according to some embodiments may further include a first gate metal oxide film GMOX1.

The first gate metal oxide film GMOX1 may be disposed between the first word line WL1 and the first active pattern AP1, and between the second word line WL2 and the second active pattern AP2. The first gate metal oxide film GMOX1 may be disposed between the first word line WL1 and the first gate liner GSL1, and between the second word line WL2 and the first gate liner GSL1. For example, the first gate metal oxide film GMOX1 may come into contact with the first word line WL1 and the second word line WL2.

For example, the first gate metal oxide film GMOX1 may include a second metal oxide. The second metal oxide may be an oxide of a second metal element included in the first word line WL1 and the second word line WL2. When the first word line WL1 and the second word line WL2 include titanium nitride (TiN), the second metal oxide may be titanium oxide. The first gate metal oxide film GMOX1 may include titanium oxide.

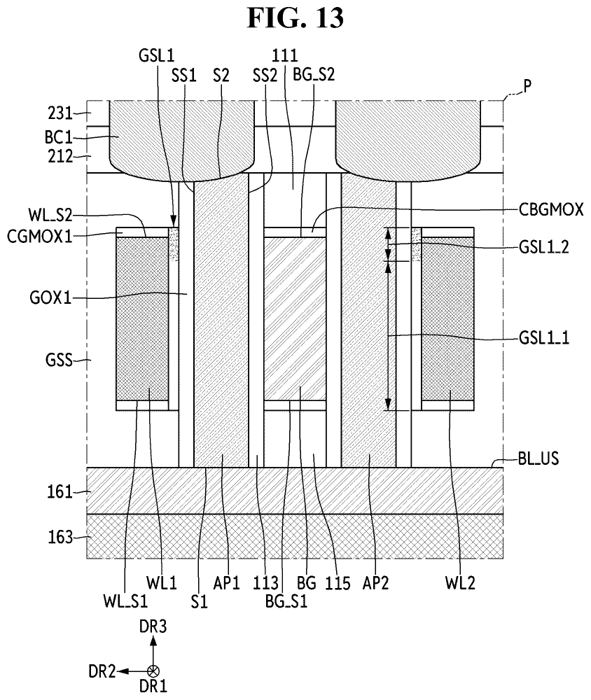

Referring to FIG. 13, the semiconductor memory device according to some embodiments may further include a first capping gate metal oxide film CGMOX1.

The first capping gate metal oxide film CGMOX1 may be disposed on the first face WL_S1 of the first and second word lines WL1 and WL2. The first capping gate metal oxide film CGMOX1 may be disposed on the second face WL_S2 of the first and second word lines WL1 and WL2. The first capping gate metal oxide film CGMOX1 may come into contact with the first and second word lines WL1 and WL2.

The back gate capping metal oxide film CBGMOX may be disposed between the back gate electrode BG and the back gate capping pattern 115. The back gate capping metal oxide film CBGMOX may be disposed between the back gate electrode BG and the back gate separation pattern 111.

The back gate capping metal oxide film CBGMOX may be disposed on the first face BG_S1 of the back gate electrode. The back gate capping metal oxide film CBGMOX may be disposed on the second face BG_S2 of the back gate electrode. The back gate capping metal oxide film CBGMOX may come into contact with the back gate electrode BG.

The back gate metal oxide film (BGMOX of FIG. 10) may be disposed between the back gate electrode BG and the first active pattern AP1, and between the back gate electrode BG and the second active pattern AP2.

As an example, the back gate capping metal oxide film CBGMOX may not be disposed on the first face BG_S1 of the back gate electrode and the second face BG_S2 of the back gate electrode. As an example, the first capping gate metal oxide film CGMOX1 may not be disposed on the first face WL_S1 of the first and second word lines WL1 and WL2 and the second face WL_S2 of the first and second word lines WL1 and WL2.

The back gate metal oxide film BGMOX may include a first metal oxide. When the back gate electrode BG includes titanium nitride (TiN), the first metal oxide may be titanium oxide. The back gate metal oxide film BGMOX and the back gate capping metal oxide film CBGMOX may include titanium oxide.

The first capping gate metal oxide film CGMOX1 may include a second metal oxide. When the first word line WL1 and the second word line WL2 include titanium nitride (TiN), the second metal oxide may be titanium oxide. The first capping gate metal oxide film CGMOX1 may include titanium oxide.

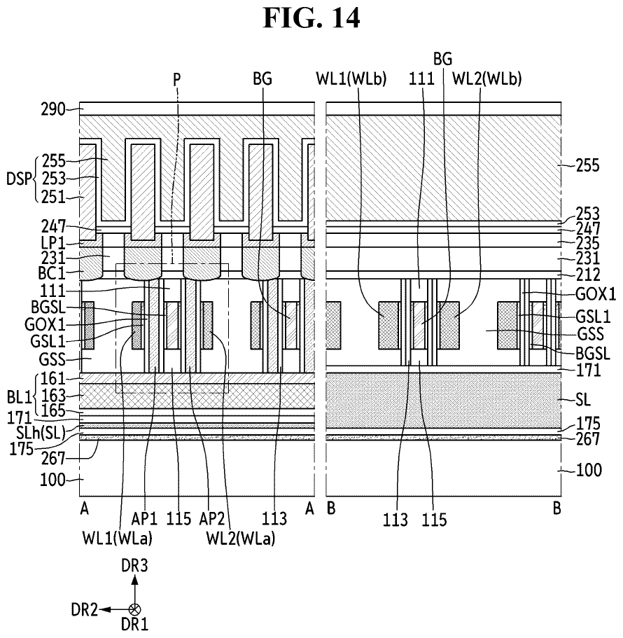

FIGS. 14, 15, and 16 are diagrams for explaining a semiconductor memory device according to some embodiments. For convenience of explanation, differences from those described using FIGS. 1 to 6 will be mainly explained.

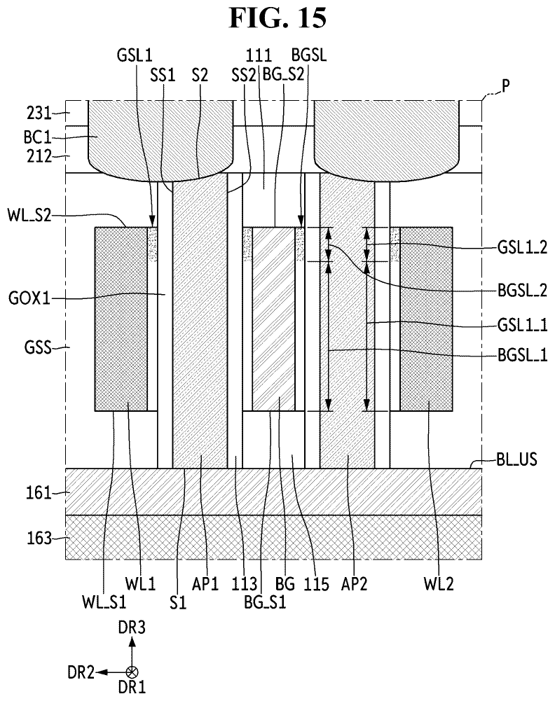

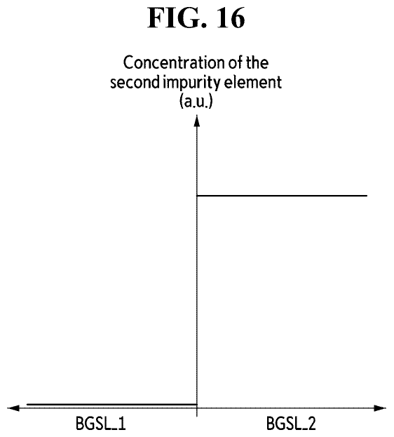

For reference, FIG. 15 is an enlarged view of a portion P of FIG. 14. FIG. 16 is a diagram for explaining a change in the second impurity concentration along the third direction DR3 in the back gate liner.

Referring to FIGS. 14, 15, and 16, the semiconductor memory device according to some embodiments may further include a back gate liner BGSL.

The back gate liner BGSL may be disposed between the back gate electrode BG and the back gate insulating film 113. The back gate liner BGSL may be disposed between the back gate electrode BG and the first active pattern AP1, and between the back gate electrode BG and the second active pattern AP2.

The back gate liner BGSL may extend along a side wall of the back gate electrode BG extending in the third direction DR3. The back gate liner BGSL may extend along a boundary between the back gate electrode BG and the back gate insulating film 113. For example, the back gate liner BGSL may come in contact with the back gate electrode BG and the back gate insulating film 113.

The back gate liner BGSL may not extend along the first face BG_S1 of the back gate electrode and the second face BG_S2 of the back gate electrode.

The back gate liner BGSL may include silicon. For example, the back gate liner BGSL may include a silicon film. The back gate liner BGSL may be a back gate silicon liner.

The back gate liner BGSL may include a first portion BGSL_1 and a second portion BGSL_2. The second portion BGSL_2 of the back gate liner may include a doped second impurity element. The first portion BGSL_1 of the back gate liner may not include the second impurity element. The second impurity element may include, for example, at least one of phosphorus (P), arsenic (As), nitrogen (N) and germanium (Ge).

For example, the second portion BGSL_2 of the back gate liner may be closer to the first contact pattern BC1 than the first portion BGSL_1 of the back gate liner. That is, the second portion BGSL_2 of the back gate liner may be closer to the data storage pattern DSP than the first portion BGSL_1 of the back gate liner.

Because a dipole due to the second impurity element between the back gate liner BGSL and the back gate insulating film 113 is formed, the work function of the transistor may be adjusted.

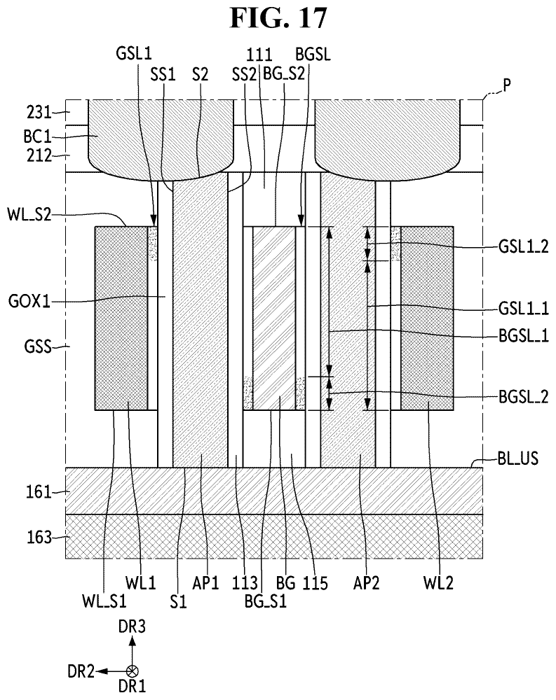

FIGS. 17 to 20 are diagrams for explaining a semiconductor memory device according to some embodiments. For convenience of explanation, differences from those explained using FIGS. 1 to 16 will be mainly explained.

Referring to FIG. 17, in the semiconductor memory device according to some embodiments, the first portion BGSL_1 of the back gate liner may be closer to the first contact pattern BC1 than the second portion BGSL_2 of the back gate liner.

In other words, the second portion BGSL_2 of the back gate liner may be closer to the first bit line BL1 than the first portion BGSL_1 of the back gate liner.

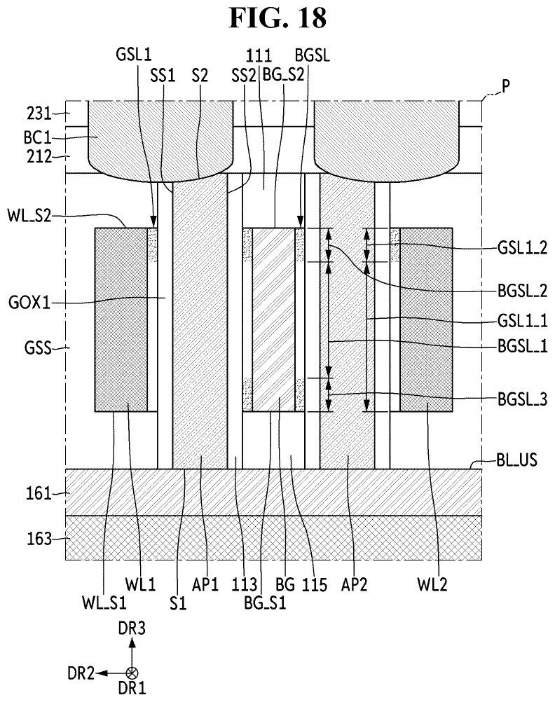

Referring to FIG. 18, in the semiconductor memory device according to some embodiments, the back gate liner BGSL may further include a third portion BGSL_3.

The first portion BGSL_1 of the back gate liner may be disposed between the second portion BGSL_2 of the back gate liner and the third portion BGSL_3 of the back gate liner. The third portion BGSL_3 of the back gate liner may be closer to the first bit line BL1 than the first portion BGSL_1 of the back gate liner.

The third portion BGSL_3 of the back gate liner may include a doped second impurity element. As an example, the second impurity element included in the third portion BGSL_3 of the back gate liner may be identical to the second impurity element included in the second portion BGSL_2 of the back gate liner. As an example, the second impurity element included in the third portion BGSL_3 of the back gate liner may be different from the second impurity element included in the second portion BGSL_2 of the back gate liner.

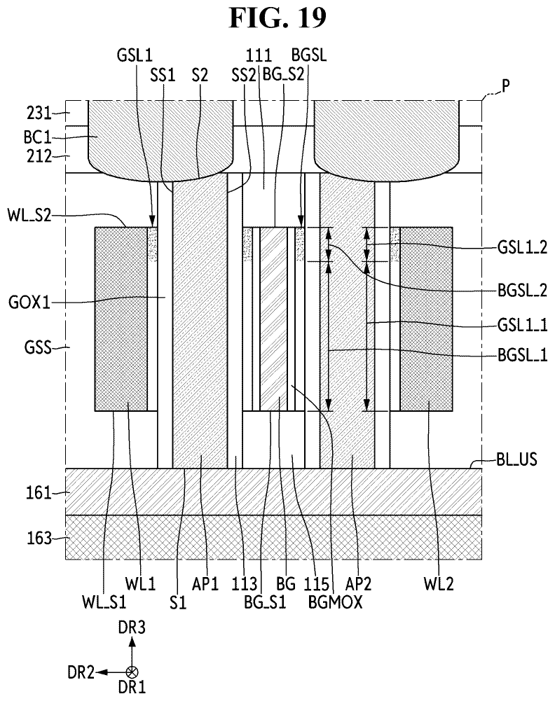

Referring to FIG. 19, the semiconductor memory device according to some embodiments may further include a back gate metal oxide film BGMOX disposed between the back gate electrode BG and the back gate liner BGSL.

The back gate metal oxide film BGMOX may extend along the boundary between the back gate electrode BG and the back gate liner BGSL. For example, the back gate metal oxide film BGMOX may come into contact with the back gate electrode BG and the back gate liner BGSL.

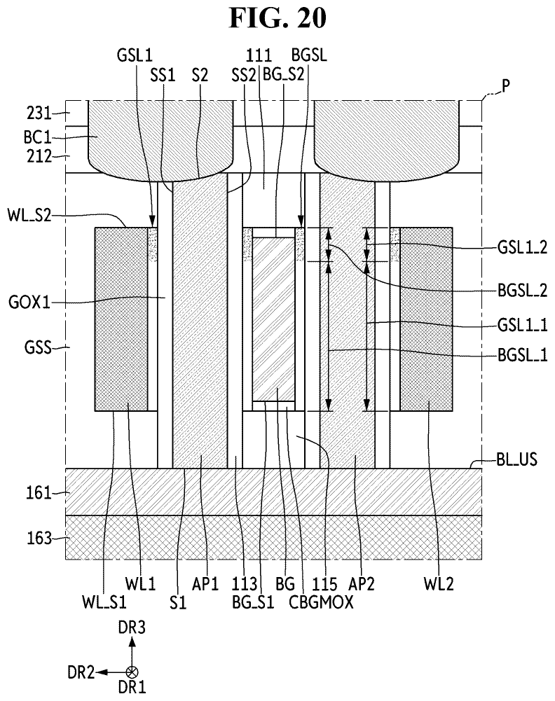

Referring to FIG. 20, a semiconductor memory device according to some embodiments may further include a back gate capping metal oxide film CBGMOX.

The back gate capping metal oxide film CBGMOX may be disposed between the back gate liners BGSL. For example, the back gate capping metal oxide film CBGMOX may come into contact with the back gate liner BGSL.

Although not shown, the first capping gate metal oxide film (CGMOX1 of FIG. 13) may be disposed on the first face WL_S1 of the first and second word lines WL1 and WL2. The first capping gate metal oxide film CGMOX1 may be disposed on the second face WL_S2 of the first and second word lines WL1 and WL2.

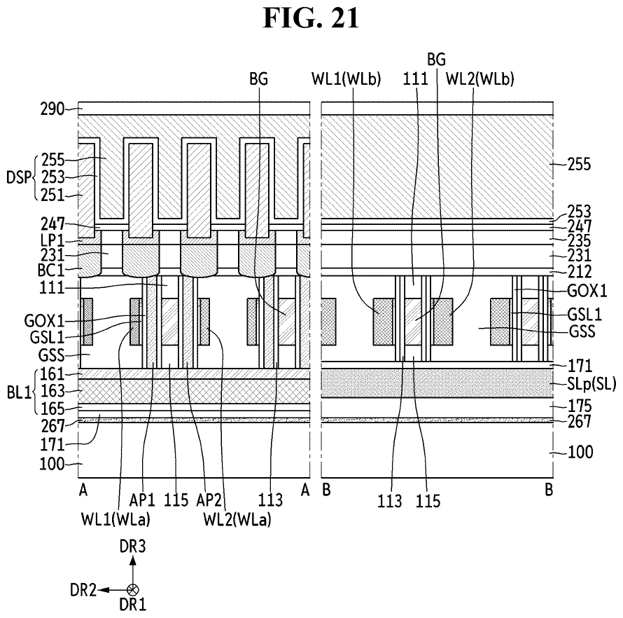

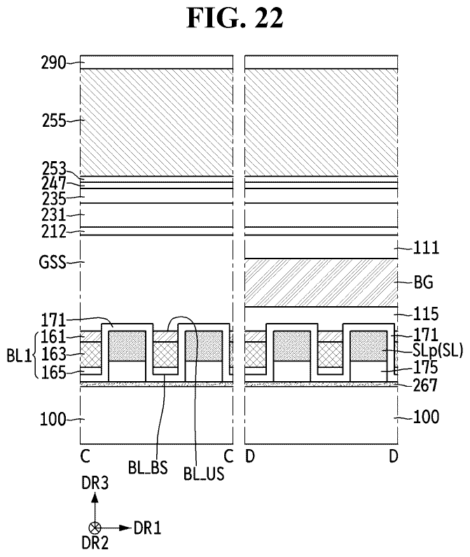

FIGS. 21 and 22 are diagrams for explaining a semiconductor memory device according to some embodiments. For convenience of explanation, differences from those described using FIGS. 1 to 6 will be mainly described.

For reference, FIG. 21 is a cross-sectional view taken along lines A-A and B-B of FIG. 1. FIG. 22 is a cross-sectional view taken along lines C-C and D-D of FIG. 1.

Referring to FIGS. 21 and 22, in the semiconductor memory device according to some embodiments, the shielding conductive pattern SL may include a plurality of shielding conductive line patterns SLp without a shielding conductive plate SLh.

The shielding conductive pattern SL may not be disposed on the bottom face BL_BS of the first bit line. For example, the shielding insulating capping film 175 may come in contact with the shielding conductive line pattern SLp.

The shielding insulating capping film 175 may have a linear shape extending in the second direction DR2 along the shielding conductive line pattern SLp.

The shielding insulating capping film 175 may have a flat plate shape. In other words, the shielding insulating capping film 175 may overlap the shielding conductive line pattern SLp and the first bit line BL1 in the third direction DR3.

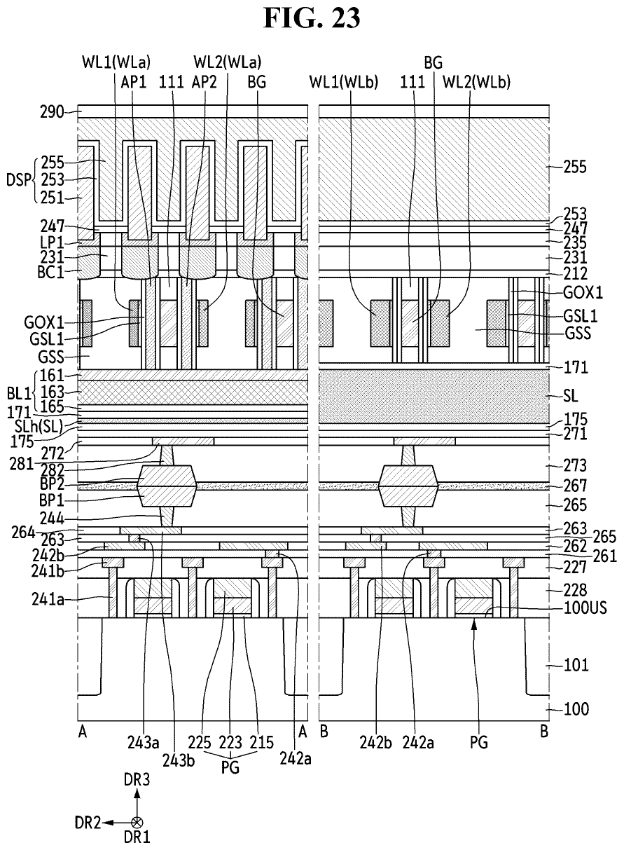

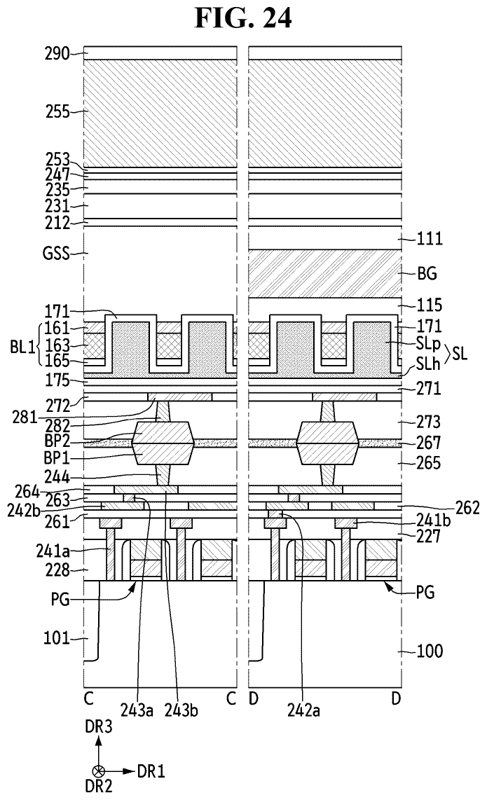

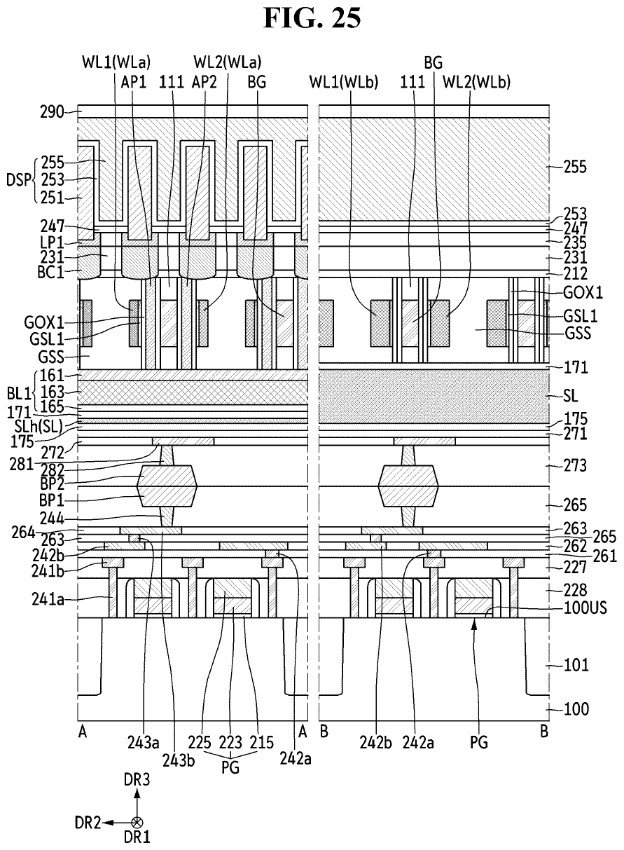

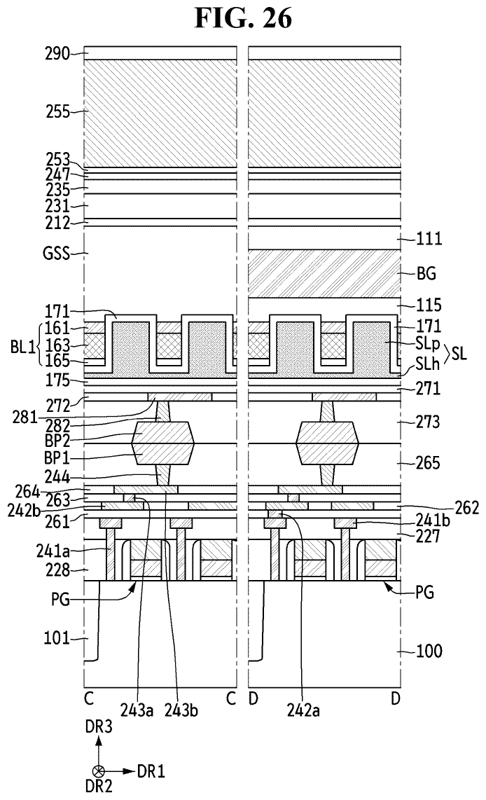

FIGS. 23 and 24 are diagrams for explaining a semiconductor memory device according to some embodiments. FIGS. 25 and 26 are diagrams for explaining a semiconductor memory device according to some embodiments. For convenience of explanation, differences from those explained using FIGS. 1 to 6 will be mainly explained.

For reference, FIGS. 23 and 25 are cross-sectional views taken along lines A-A and B-B of FIG. 1, respectively. FIGS. 24 and 26 are cross-sectional views taken along lines C-C and D-D of FIG. 1, respectively.

Referring to FIGS. 23, 24, 25, and 26, the semiconductor memory device according to some embodiments may further include a peri-gate structure PG disposed between the substrate 100 and the first bit line BL1.

The peri-gate structure PG may be disposed on the substrate 100. For example, the peri-gate structure PG may be disposed on the upper face 100US of the substrate. The peri-gate structure PG may be disposed over the cell array region and the peripheral circuit region. In other words, a part of the peri-gate structure PG may be disposed in the cell array region of the substrate 100, and the rest of the peri-gate structure PG may be disposed in the peripheral circuit region of the substrate 100.

The peri-gate structure PG may be included in a sensing transistor, a transfer transistor, a drive transistor, or the like. For example, the peri-gate structure PG included in the sensing transistor may be, but is not limited to, being disposed on the cell array region of the substrate 100. The types of transistors of the peripheral circuit disposed on the cell array region of the substrate 100 may vary depending on the design placement of the semiconductor memory device.

The peri-gate structure PG may include a peri-gate insulating film 215, a peri-lower conductive pattern 223, and a peri-upper conductive pattern 225. The peri-gate insulating film 215 may include, but is not limited to, at least one of a silicon oxide film, a silicon oxynitride film, a high dielectric constant insulating film having a higher dielectric constant than a silicon oxide film, or a combination thereof. The high dielectric constant insulating film may include, for example, but not limited to, at least one of metal oxide, metal oxynitride, metal silicon oxide, and metal silicon oxynitride.

The peri-lower conductive pattern 223 and the peri-upper conductive pattern 225 each include a conductive material. For example, the peri-lower conductive pattern 223 and the peri-upper conductive pattern 225 may each include at least one of a doped semiconductor material, a conductive metal nitride, a conductive metal silicon nitride, a metal carbonitride, a conductive metal silicide, a conductive metal oxide, a two-dimensional (2D) material, and a metal. Although the peri-gate structure PG is shown to include a plurality of conductive patterns, the embodiment is not limited thereto.

Although it is not shown, the peri-gate structure PG may further include a peri-gate mask pattern disposed on the peri-upper conductive pattern 225. The peri-gate mask pattern is formed of an insulating material.

The first peri-lower insulating film 227 and the second peri-lower insulating film 228 are disposed on the upper face 100US of the substrate. The first peri-lower insulating film 227 and the second peri-lower insulating film 228 each include an insulating material.

A peri-contact plug 241a and a peri-wiring line 241b may be disposed inside the first peri-lower insulating film 227 and the second peri-lower insulating film 228. The peri-contact plug 241a and the peri-wiring line 241b may be connected to the conductive patterns 223 and 225 of the peri-gate structure PG. Although it is not shown, the peri-contact plug 241a and the peri-wiring line 241b may be connected to a source/drain region disposed on at least one side of the peri-gate structure PG.

Although the peri-contact plug 241a and the peri-wiring line 241b are shown as being different films from each other, the embodiment is not limited thereto. A boundary between the peri-contact plug 241a and the peri-wiring line 241b may not be distinguished. The peri-contact plug 241a and the peri-wiring line 241b each include a conductive material.

The first peri-upper insulating film 261 and the second peri-upper insulating film 262 may be disposed on the peri-contact plug 241a and the peri-wiring line 241b. The first peri-upper insulating film 261 and the second peri-upper insulating film 262 each include an insulating material. An insulating film formed of a single film may be disposed on the peri-contact plug 241a and the peri-wiring line 241b.

The first peri-connecting structures 242a and 242b may be connected to the peri-wiring line 241b. The first peri-connecting structures 242a and 242b may include a first peri-connecting via 242a and a first peri-connecting wiring 242b. The first peri-connecting via 242a and the first peri-connecting wiring 242b each include a conductive material. Although the first peri-connecting via 242a and the first peri-connecting wiring 242b are shown as being formed of films different from each other, the embodiment is not limited thereto.

A third peri-upper insulating film 263 and a fourth peri-upper insulating film 264 may be disposed on the first peri-connecting structures 242a and 242b. The third peri-upper insulating film 263 and the fourth peri-upper insulating film 264 each include an insulating material. An insulating film formed of a single film may be disposed on the first peri-connecting structures 242a and 242b.

The second peri-connecting structures 243a and 243b may be connected to the first peri-connecting wiring 242b. The second peri-connecting structures 243a and 243b may include a second peri-connecting via 243a and a second peri-connecting wiring 243b. The second peri-connecting via 243a and the second peri-connecting wiring 243b each include a conductive material. Although the second peri-connecting via 243a and the second peri-connecting wiring 243b are shown as being films different from each other, the embodiment is not limited thereto.

Although the first peri-connecting structures 242a and 242b and the second peri-connecting structures 243a and 243b are shown as being disposed on the peri-gate structure PG, the embodiment is not limited thereto. In example embodiments, only one peri-connecting structure may be disposed on the peri-gate structure PG.

A fifth peri-upper insulating film 265 may be disposed on the second peri-connecting structures 243a and 243b. The fifth peri-upper insulating film 265 includes an insulating material.

A lower bonding pad BP1 may be disposed on the peri-gate structure PG. The lower bonding pad BP1 may be connected to the second peri-connecting structures 243a and 243b.

For example, at least one of the lower bonding pads BP1 may be connected to the peri-gate structure PG. At least the other of the lower bonding pads BP11 may be connected to a source/drain region disposed on at least one side of the peri-gate structure PG.

A lower pad plug 244 may connect the lower bonding pad BP1 and the second peri-connecting wiring 243b. The lower bonding pad BP1 and the lower pad plug 244 may be disposed inside the fifth peri-upper insulating film 265.

A first cell lower insulating film 271, a second cell lower insulating film 272, and a third cell lower insulating film 273 may be disposed on the fifth peri-upper insulating film 265. The first cell lower insulating film 271, the second cell lower insulating film 272, and the third cell lower insulating film 273 may be disposed on the lower bonding pad BP1.

The second cell lower insulating film 272 may be disposed between the first cell lower insulating film 271 and the third cell lower insulating film 273. The first cell lower insulating film 271 may be disposed between the second cell lower insulating film 272 and the fifth peri-upper insulating film 265. The first cell lower insulating film 271, the second cell lower insulating film 272, and the third cell lower insulating film 273 each include an insulating material.

An upper bonding pad BP2 may be disposed on the lower bonding pad BP1. The upper bonding pad BP2 may be disposed on the fifth peri-upper insulating film 265.

The upper bonding pad BP2 may be connected to the lower bonding pad BP1. The upper bonding pad BP2 may come into contact with the lower bonding pad BP1.

A cell connecting wiring 281 may be disposed on the upper bonding pad BP2. The cell connecting wiring 281 may be disposed between the upper bonding pad BP2 and the first bit line BL1. The cell connecting wiring 281 may be disposed between the upper bonding pad BP2 and the shielding conductive pattern SL.

Although it is not shown, the cell connecting wiring 281 may be connected to at least one of the first bit line BL1 and the shielding conductive pattern SL.

Although the cell connecting wiring 281 disposed on one metal level is shown as being disposed between the upper bonding pad BP2 and the first bit line BL1, this is only for convenience of explanation, and the embodiment is not limited thereto. A plurality of cell connecting wirings 281 disposed on metal levels different from each other may be disposed between the upper bonding pad BP2 and the first bit line BL1.

The upper pad plug 282 may connect the upper bonding pad BP2 and the cell connecting wiring 281. The upper bonding pad BP2 may be connected to the cell connecting wiring 281 through the upper pad plug 282.

The upper bonding pad BP2 and the upper pad plug 282 may be disposed inside the third cell lower insulating film 273. The cell connecting wiring 281 may be disposed inside the second cell lower insulating film 272.

The upper pad plug 282 and the lower pad plug 244 may include a conductive material including a metal. The lower bonding pad BP1 and the upper bonding pad BP2 may each include a conductive material including a metal. The cell connecting wiring 281 may include a conductive material including a metal.

Although the lower bonding pad BP1 and the upper bonding pad BP2 are each shown as being a single film, this is only for convenience of explanation, and the example embodiments are not limited thereto. Although the upper pad plug 282 and the lower pad plug 244 are each shown as being a single film, the embodiment is not limited thereto. Although the cell connecting wiring 281 is shown as being a single film, the embodiment is not limited thereto.

The shielding conductive pattern SL and the first bit line BL1 may be disposed on the peri-gate structure PG. The shielding conductive pattern SL and the first bit line BL1 may be disposed on the upper bonding pad BP2. For example, the shielding conductive pattern SL and the first bit line BL1 may be disposed on the cell connecting wiring 281.

The first cell lower insulating film 271 may be disposed between the first bit line BL1 and the cell connecting wiring 281, and between the shielding conductive pattern SL and the cell connecting wiring 281. The first cell lower insulating film 271 may be disposed between the shielding insulating liner 171 and the second cell lower insulating film 272, and between the shielding insulating capping film 175 and the second cell lower insulating film 272.

The cell upper insulating film 290 may be disposed on the data storage pattern DSP. The cell upper insulating film 290 includes an insulating material.

In FIGS. 23 and 24, the bonding insulating film 267 may be disposed between the third cell lower insulating film 273 and the fifth peri-upper insulating film 265. The bonding insulating film 267 may be disposed between the peri-gate structure PG and the shielding conductive pattern SL.

The bonding insulating film 267 may be disposed along an extension line of the interface between the lower bonding pad BP1 and the upper bonding pad BP2. The interface between the lower bonding pad BP1 and the upper bonding pad BP2 may be a boundary between the lower bonding pad BP1 and the upper bonding pad BP2.

In FIGS. 25 and 26, the bonding insulating film (267 of FIGS. 23 and 24) may not be disposed along the extension line of the interface between the lower bonding pad BP1 and the upper bonding pad BP2. The third cell lower insulating film 273 may come into contact with the fifth peri-upper insulating film 265.

A width of the lower bonding pad BP1 may be identical to a width of the upper bonding pad BP2 at the interface between the lower bonding pad BP1 and the upper bonding pad BP2. The width of the lower bonding pad BP1 may be different from the width of the upper bonding pad BP2 at the interface between the lower bonding pad BP1 and the upper bonding pad BP2.

At the interface between the lower bonding pad BP1 and the upper bonding pad BP2, the lower bonding pad BP1 may be aligned with the upper bonding pad BP2. The lower bonding pad BP1 may be misaligned with the upper bonding pad BP2 at the interface between the lower bonding pad BP1 and the upper bonding pad BP2.

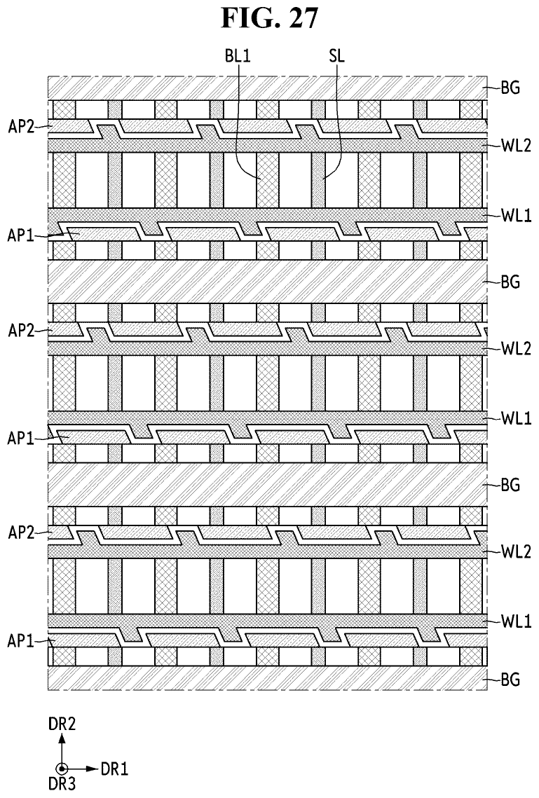

FIGS. 27, 28, 29, and 30 are diagrams for explaining a semiconductor memory device according to some embodiments, respectively. For convenience of explanation, the explanation will focus on the points that are different from those explained using FIGS. 1-26.

Referring to FIG. 27, in the semiconductor memory device according to some embodiments, the first and second active patterns AP1 and AP2 may be arranged alternately in a diagonal direction with respect to the first direction DR1 and the second direction DR2. Here, the diagonal direction may be parallel to the upper face of the substrate 100.

Each of the first and second active patterns AP1 and AP2 may have a parallelogram shape or a rhombus shape from the planar viewpoint. Since the first and second active patterns AP1 and AP2 are disposed in the diagonal direction, coupling between the first and second active patterns AP1 and AP2 facing each other in the second direction DR2 may be reduced.

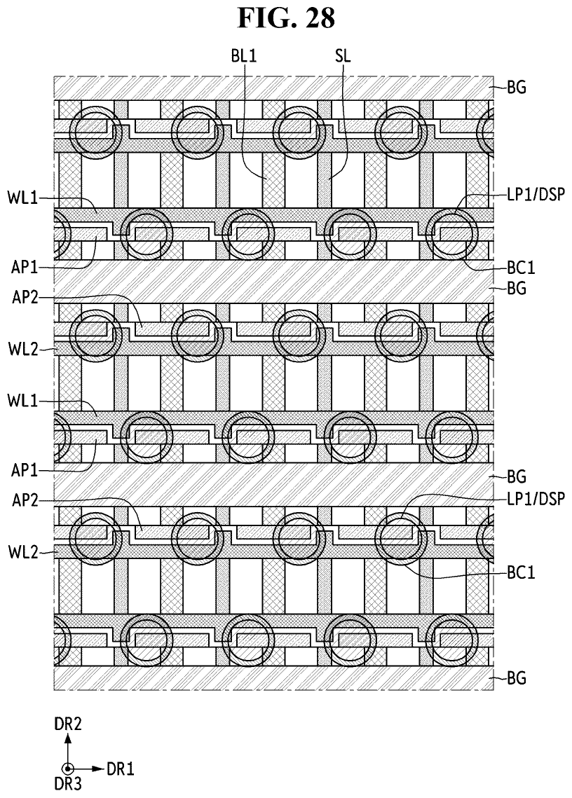

Referring to FIG. 28, in the semiconductor memory device according to some embodiments, the first landing pads LP1 and the data storage patterns DSP may be arranged in a zigzag or honeycomb form from the planar viewpoint.

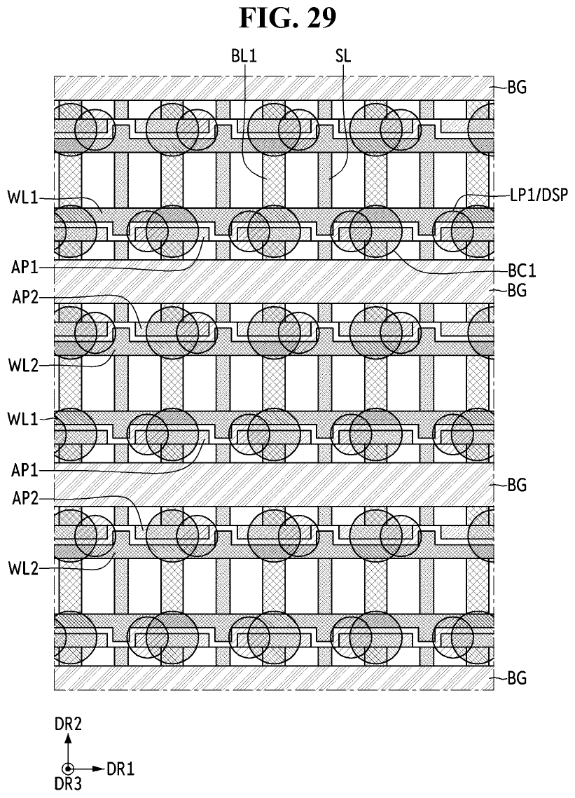

Referring to FIG. 29, in the semiconductor memory device according to some embodiments, the data storage patterns DSP may be disposed to be misaligned from the landing pads LP from the planar viewpoint.

Each of the data storage patterns DSP may come into contact with a part of the first landing pad LP1.

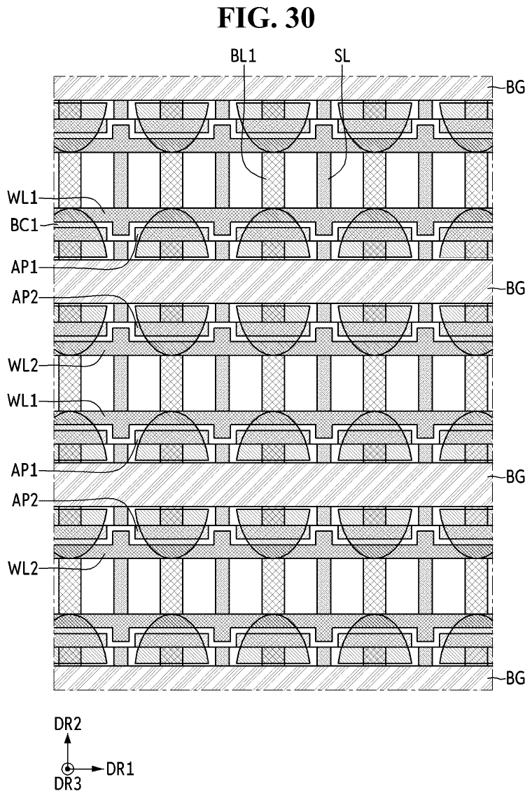

Referring to FIG. 30, in the semiconductor memory device according to some embodiments, each of the first contact patterns BC1 disposed on the first and second active patterns AP1 and AP2 may have a semicircular shape or a semi-elliptical shape from the planar viewpoint.

The first contact patterns BC1 may be disposed symmetrically with each other with the back gate electrode BG interposed between them from the planar viewpoint.

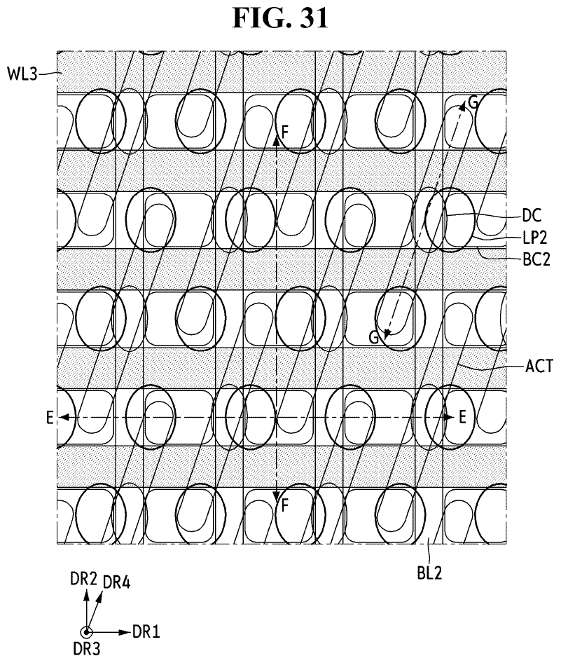

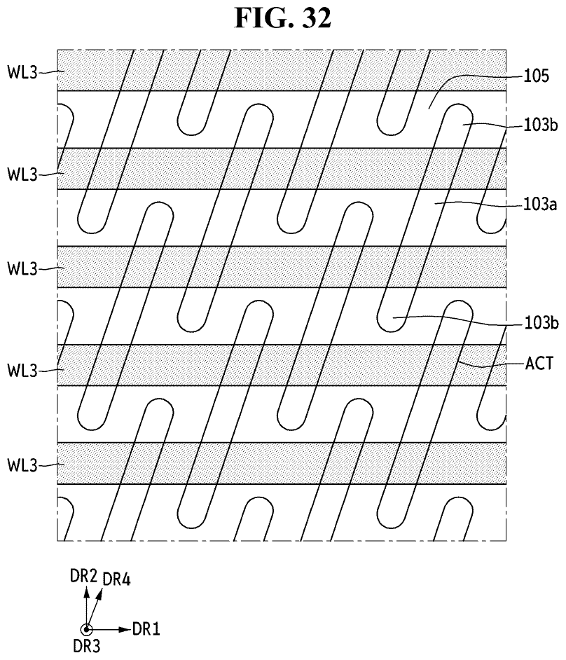

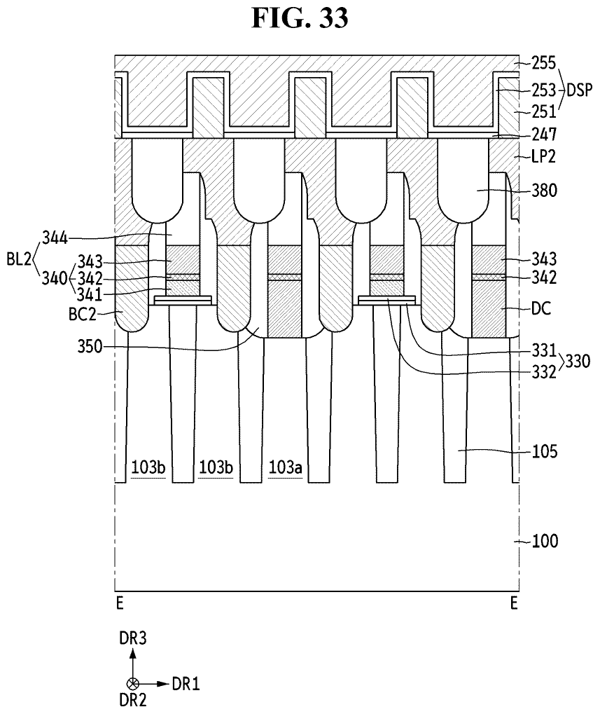

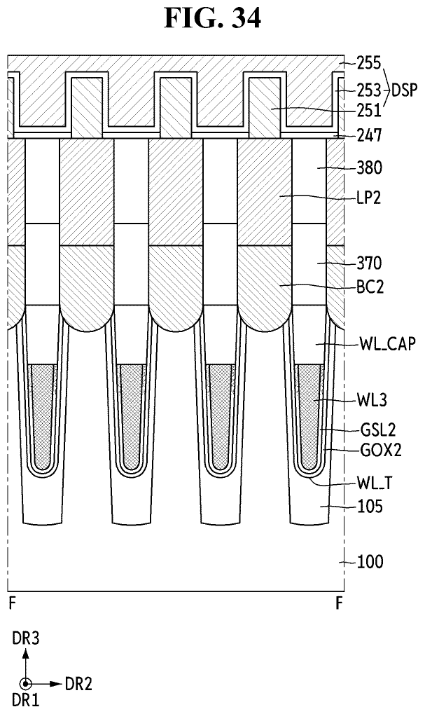

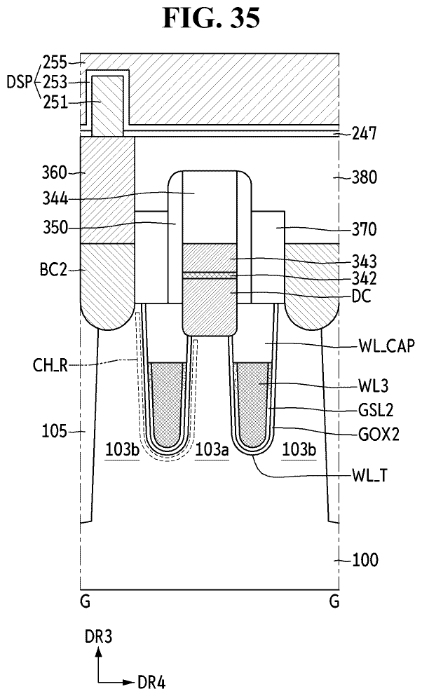

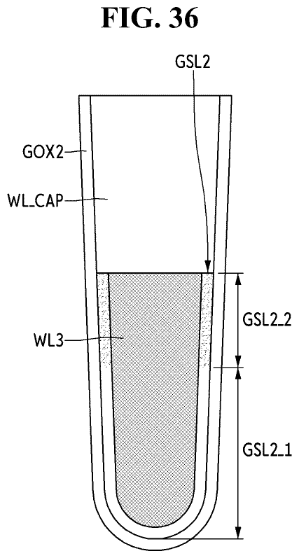

FIG. 31 is a layout diagram for explaining a semiconductor memory device according to some embodiments. FIG. 32 is a layout showing only a third word line and the cell active region of FIG. 31. FIGS. 33, 34, and 35 are cross-sectional views taken along E-E, F-F, and G-G of FIG. 31. FIG. 36 is an enlarged view for explaining the third word line, the second gate insulating film, the second gate liner, and the like of FIGS. 34 and 35.

The semiconductor memory device according to some embodiments of the present disclosure may include memory cells including a buried channel array transistor (BCAT).

Referring to FIGS. 31 and 32, a semiconductor memory device according to some embodiments may include a plurality of cell active regions ACT.

The cell active regions ACT may be defined by an element separation film 105 formed in a substrate (100 of FIG. 33). With a reduction in design rules of the semiconductor memory device, the active regions ACT may be disposed in the form of a bar of a diagonal line or an oblique line as shown. For example, the cell active regions ACT may extend in a fourth direction DR4.

A plurality of gate electrodes which extend in the first direction DR1 across the active region ACT may be disposed. The plurality of gate electrodes may extend to be parallel to each other. The plurality of gate electrodes may be, for example, a plurality of third word lines WL3. The third word lines WL3 may be disposed at equal intervals. A width of the third word lines WL3 and an interval between the third word lines WL3 may be determined depending on a design rule.

A plurality of second bit lines BL extending in the second direction DR2 perpendicular to the third word lines WL3 may be disposed on the third word lines WL3. The plurality of second bit lines BL may extend to be parallel to each other. The second bit lines BL2 may be disposed at equal intervals. A width of the second bit lines BL2 and an interval between the second bit lines BL2 may be determined depending on a design rule.

Each cell active region ACT may be divided into three portions by two third word lines WL3 extending in the first direction DR1. The cell active region ACT may include a first portion 103a, and a second portion 103b defined on both sides of the first portion 103a. The first portion 103a of the cell active region ACT may be located at the center portion of the cell active region ACT, and the second portion 103b of the cell active region ACT may be located at an end portion of the cell active region ACT. For example, the first portion 103a of the cell active region ACT may be a region connected to the second bit line BL2, and the second portion 103b of the cell active region ACT may be a region connected to the data storage pattern (DSP of FIG. 29). In other words, a common drain region may be located at the first portion 103a of the cell active region ACT, and a source region may be located at the second portion 103b of the cell active region ACT.

The fourth direction DR4 may be perpendicular to the third direction DR3. The fourth direction DR4 may be disposed on the same plane as the first direction DR1 and the second direction DR2.

The semiconductor memory device according to some embodiments may include various contact arrangements formed on the cell active region ACT. The various contact arrangements may include, for example, a direct contact DC, a second contact pattern BC2, a second landing pad LP2, and the like.

Here, the direct contact DC may refer to a contact that electrically connects the cell active region ACT to the second bit line BL2. The second contact pattern BC2 may refer to a contact that connects the cell active region ACT to the storage electrode (251 of FIG. 29) of the data storage pattern DSP. Due to the layout structure, the contact area between the second contact pattern BC2 and the cell active region ACT may be small. Therefore, a conductive second landing pad LP2 may be introduced to expand the contact area with the cell active region ACT and the contact area with the storage electrode (251 of FIG. 29).

The second landing pad LP2 may be disposed between the cell active region ACT and the second contact pattern BC2, or may be disposed between the second contact pattern BC2 and the storage electrode (251 of FIG. 29). In the semiconductor memory device according to some embodiments, the second landing pad LP may be disposed between the second contact pattern BC2 and the storage electrode (251 of FIG. 29). The contact resistance between the cell active region ACT and the storage electrode (251 of FIG. 29) may be reduced, by expanding the contact area through the introduction of the second landing pad LP2.

The direct contact DC may be disposed at a central portion of the cell active region ACT. The direct contact DC may be connected to the first portion 103a of the cell active region ACT. The second contact pattern BC2 may be disposed at both end portions of the cell active region ACT. The second contact pattern BC2 may be connected to the second portion 103b of the cell active region ACT.

As the second contact pattern BC2 is disposed at both end portions of the cell active region ACT, the second landing pad LP2 may be disposed to be adjacent to both ends of the cell active region ACT and to overlap the second contact pattern BC2. In other words, the second contact pattern BC2 may be formed to overlap the cell active region ACT and the element separation film 105 between the adjacent third word lines WL3 and between the adjacent second bit lines BL2.

The third word line WL3 may be formed as a structure buried in the substrate 100. The third word line WL3 may be disposed across the cell active region ACT between the direct contact DC and the second contact pattern BC2. As shown, two third word lines WL3 may be disposed to cross one cell active region ACT. Since the cell active region ACT extends along the fourth direction DR4, the third word line WL3 may have an angle of less than 90 degrees with the cell active region ACT.

The direct contact DC and the second contact pattern BC2 may be disposed symmetrically. Accordingly, the direct contact DC and the second contact pattern BC2 may be disposed on a straight line along the first direction DR1 and the second direction DR2.

On the other hand, unlike the direct contact DC and the second contact pattern BC2, the second landing pads LP2 may be disposed in the form of zigzag in the second direction DR2 in which the second bit lines BL2 extend. Also, the second landing pads LP2 may be disposed to overlap the same side face portions of the second bit lines BL2 in the first direction DR1 in which the third word lines WL3 extend.

For example, each of the second landing pads LP2 of the first line may overlap a left side of the corresponding second bit line BL2, and each of the second landing pads LP2 of the second line may overlap a right side of the corresponding second bit line BL2.

Referring to FIGS. 31-36, the semiconductor memory device according to some embodiments may include a third word line WL3, a second gate liner GSL2, a second bit line BL2, a direct contact DC, a second contact pattern BC2, and a data storage pattern DSP.

The element separation film 105 may be disposed inside the substrate 100. The element separation film 105 may have a shallow trench isolation (STI) structure having excellent element isolation characteristics. The cell active region ACT defined by the element separation film 105 may have a long island formation including a short axis and a long axis, as shown in FIGS. 31 and 32. The cell active region ACT may have an oblique line shape having an angle of less than 90 degrees with respect to the third word line WL3 formed in the element separation film 105. Also, the cell active region ACT may have an oblique line shape to have an angle of less than 90 degrees with respect to the second bit line BL2 formed on the element separation film 105. The element separation film 105 may include an insulating material.

The substrate 100 may include a cell gate trench WL_T. The cell gate trench WL_T may be disposed in the substrate 100 and the element separation film 105. The cell gate trench WL_T may be disposed across the cell active region ACT.

The second gate insulating film GOX2, the second gate liner GSL2, the third word line WL3, and the gate capping film WL_CAP may be disposed inside the cell gate trench WL_T. The second gate insulating film GOX2, the second gate liner GSL2, the third word line WL3, and the gate capping film WL_CAP may be included in the buried cell gate structure.

In FIG. 35, the substrate 100 may include a buried channel region CH_R defined along the profile of the cell gate trench WL_T. The first portion 103a of the cell active region ACT, the second portion 103b of the cell active region ACT, and the third word line WL3 may constitute a buried channel transistor. The buried channel region CH_R may be a channel region of the buried channel transistor.

The third word line WL3 may extend in the first direction DR1 inside the cell gate trench WL_T. The third word line WL3 may include a conductive material. The third word line WL3 may include at least one of, for example, a conductive semiconductor material, a conductive metal nitride, a conductive metal silicon nitride, a metal carbonitride, a conductive metal silicide, a two-dimensional material, and a metal.

In the semiconductor memory device according to some embodiments, the third word line WL3 may include a third metal element. For example, the third metal element may be titanium (Ti). The third word line WL3 may include titanium nitride (TiN).

The second gate insulating film GOX2 may be disposed between the substrate 100 and the third word line WL3. For example, the second gate insulating film GOX2 may be disposed between the buried channel region CH_R and the third word line WL3.

The second gate insulating film GOX2 may extend along the profile of the cell gate trench WL_T. The second gate insulating film GOX2 may be made up of an insulating material. The second gate insulating film GOX2 may include, but not limited to, silicon oxide.

The second gate liner GSL2 may be disposed between the third word line WL3 and the buried channel region CH_R. The second gate liner GSL2 may be disposed between the third word line WL3 and the second gate insulating film GOX2.

The second gate liner GSL2 may extend along the boundary between the third word line WL3 and the second gate insulating film GOX2. In the semiconductor memory device according to some embodiments, the second gate liner GSL2 may come into contact with the third word line WL3 and the second gate insulating film GOX2.

The second gate liner GSL2 may include silicon. For example, the second gate liner GSL2 may include a silicon film. The second gate liner GSL2 may be a gate silicon liner.

The second gate liner GSL2 may include a first portion GSL2_1 and a second portion GSL2_2. The second portion GSL2_2 of the second gate liner is closer to the direct contact DC and the second contact pattern BC2 than the first portion GSL2_1 of the second gate liner.

The second portion GSL2_2 of the second gate liner may include a doped third impurity element. The first portion GSL2_1 of the second gate liner may not include the third impurity element. The third impurity element may include at least one of, for example, phosphorus (P), arsenic (As), nitrogen (N), and germanium (Ge).

The second gate insulating film GOX2 may include a first portion and a second portion. The first portion of the second gate insulating film GOX2 may overlap the first portion GSL2_1 of the second gate liner in the second direction DR2. The second portion of the second gate insulating film GOX2 may overlap the second portion GSL2_2 of the second gate liner in the second direction DR2.

As an example, the second portion of the second gate insulating film GOX2 may not include the third impurity element. As an example, the second portion of the second gate insulating film GOX2 may include the third impurity element.

The gate capping film WL_CAP may be disposed on the third word line WL3. The gate capping film WL_CAP may be disposed inside the cell gate trench WL_T. The gate capping film WL_CAP may include, but not limited to, silicon nitride.

The second bit line BL2 may include a cell conductive line 340 and a bit line capping film 344.

The cell conductive line 340 may be disposed on the substrate 100 and the element separation film 105 on which the third word line WL3 is formed. The cell conductive line 340 may cross the element separation film 105 and the cell active region ACT defined by the element separation film 105. The cell conductive line 340 may be disposed to intersect the third word line WL3.

The cell conductive line 340 may include, for example, at least one of a semiconductor material doped with impurities, a conductive silicide compound, a conductive metal nitride, a two-dimensional material, a metal, and a metal alloy.

The cell conductive line 340 may be a single film or a double film, but may also be a multi-layer film including a first conductive line 341, a second conductive line 342, and a third conductive line 343 as shown. The cell conductive line 340 is shown as a triple film, but is not limited thereto. That is, the cell conductive line 340 may include either a single film or a plurality of conductive films in which conductive materials are stacked.

The bit line capping film 344 may be disposed on the cell conductive line 340. The bit line capping film 344 may extend in the second direction DR2 along the upper face of the cell conductive line 340. The bit line capping film 344 may include, for example, at least one of a silicon nitride film, a silicon oxynitride, a silicon carbonitride, and a silicon oxycarbonitride.

In the semiconductor memory device according to some embodiments, the bit line capping film 344 may include a silicon nitride film. The bit line capping film 344 is shown as being a single film, but is not limited thereto.

The direct contact DC may be disposed between the cell conductive line 340 and the substrate 100. In other words, the cell conductive line 340 may be disposed on the direct contact DC. For example, the direct contact DC may be formed at a point on which the cell conductive line 340 intersects a center portion of the cell active region ACT having a long island shape. The direct contact DC may be disposed between the first portion 103a of the cell active region ACT and the cell conductive line 340. The direct contact DC may electrically connect the cell conductive line 340 and the substrate 100. The direct contact DC may include, for example, at least one of an impurity-doped semiconductor material, a conductive silicide compound, a conductive metal nitride, and a metal.

The first bit line insulating film 330 may be disposed on the substrate 100 and the element separation film 105. More specifically, the first bit line insulating film 330 may be disposed on the upper face of the substrate 100 and the element separation film 105 on which the direct contact DC and the second contact pattern BC2 are not formed. The first bit line insulating film 330 may be disposed between the substrate 100 and the cell conductive line 340, and between the element separation film 105 and the cell conductive line 340.

Although the first bit line insulating film 330 may be a single film, as shown, the cell insulating film 330 may be a multi-layer film including a first cell insulating film 331 and a second cell insulating film 332. For example, although the first cell insulating film 331 may include a silicon oxide film, and the second cell insulating film 332 may include a silicon nitride film, the embodiment is not limited thereto. The cell insulating film 330 may be a triple film including, but not limited to, a silicon oxide film, a silicon nitride film, and a silicon oxide film.

The first bit line spacer 350 may be disposed on the side wall of the second bit line BL2. The first bit line spacer 350 may be disposed on the side wall of the cell conductive line 340 and the side wall of the bit line capping film 344. In the portion of the cell conductive line 340 in which the direct contact DC is formed, the first bit line spacer 350 may be disposed on the substrate 100 and the element separation film 105. The first bit line spacer 350 may be disposed on the side wall of the cell conductive line 340, the side wall of the bit line capping film 344, and the side wall of the direct contact DC. In the remaining portion of the cell conductive line 340 in which the direct contact DC is not formed, the first bit line spacer 350 may be disposed on the first bit line insulating film 330. The first bit line spacer 350 may be disposed on the side wall of the cell conductive line 340 and the side wall of the bit line capping film 344.

Although the first bit line spacer 350 is shown as being a single film, this is only for convenience of explanation, and the embodiment is not limited thereto. In other words, the first bit line spacer 350 may have a multi-layer film structure. The first bit line spacer 350 may include, for example, but is not limited to, a silicon oxide film, a silicon nitride film, a silicon oxynitride film (SiON), a silicon oxycarbonitride film (SiOCN), air, and combinations thereof.

A fence pattern 370 may be disposed on the substrate 100 and the element separation film 105. The fence pattern 370 may be disposed to overlap the third word line WL3 formed inside the substrate 100 and the element separation film 105.

The fence pattern 370 may be disposed between the second bit lines BL2 extending in the second direction DR2. The fence pattern 370 may include, for example, at least one of silicon oxide, silicon nitride, silicon oxynitride, and combinations thereof.

The second contact pattern BL2 may be disposed between the cell conductive lines 340 adjacent to each other in the first direction DR1. The second contact pattern BL2 may be disposed on both sides of the cell conductive line 340. More specifically, the second contact pattern BL2 may be disposed between the second bit lines BL2. The second contact pattern BL2 may be disposed between the fence patterns 370 adjacent to each other in the second direction DR2.

The second contact pattern BL2 may overlap the substrate 100 and the element separation film 105 between the adjacent cell conductive lines 340. The second contact pattern BL2 may be connected to the cell active region ACT.

The second contact pattern BL2 may include, for example, at least one of a semiconductor material doped with impurities, a conductive silicide compound, a conductive metal nitride, and a metal.

The second landing pad LP2 may be disposed on the second contact pattern BL2. The second landing pad LP2 may be electrically connected to the second contact pattern BL2. The second landing pad LP2 may be connected to the second portion 103b of the active region ACT.

The second landing pad LP2 may overlap a part of the upper face of the second bit line BL2. The second landing pad LP2 may include, for example, at least one of a conductive metal nitride, a conductive metal carbide, a metal, and a metal alloy.

The pad separation insulating film 380 may be disposed on the second landing pad LP2 and the second bit line BL2. For example, the pad separation insulating film 180 may be disposed on the bit line capping film 344. The pad separation insulating film 380 may define the second landing pad LP2 that forms a plurality of isolation regions. The pad separation insulating film 380 may not cover the upper face of the second landing pad LP2.

The pad separation insulating film 380 may include an insulating material and electrically separate the plurality of second landing pads LP2 from each other. For example, the pad separation insulating film 380 may include at least one of a silicon oxide film, a silicon nitride film, a silicon oxynitride film, a silicon oxycarbonitride film, and a silicon carbonitride film.

The data storage pattern DSP may be disposed on the second landing pad LP2.

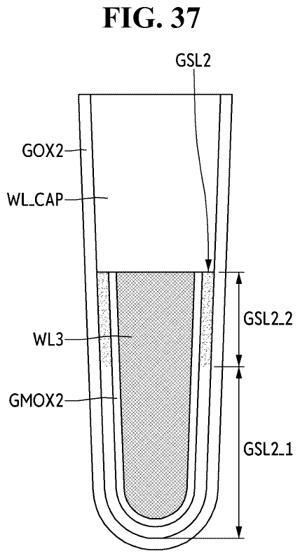

FIGS. 37-39 are diagrams for explaining a semiconductor memory device according to some embodiments. For convenience of explanation, differences from those described using FIGS. 31-6 will be mainly explained. For reference, FIGS. 37-39 are diagrams showing the buried cell gate structure of FIGS. 34 and 35, respectively.

Referring to FIG. 37, the semiconductor memory device according to some embodiments may further include a second gate metal oxide film GMOX2.

The second gate metal oxide film GMOX12 may be disposed between the third word line WL3 and the buried channel region CH_R. The second gate metal oxide film GMOX2 may be disposed between the third word line WL3 and the second gate liner GSL2. For example, the second gate metal oxide film GMOX2 may come into contact with the third word line WL3.

The second gate metal oxide film GMOX2 may include a third metal oxide. The third metal oxide may be an oxide of a third metal element included in the third word line WL3. When the third word line WL3 includes titanium nitride (TiN), the third metal oxide may be titanium oxide. The second gate metal oxide film GMOX2 may include titanium oxide.

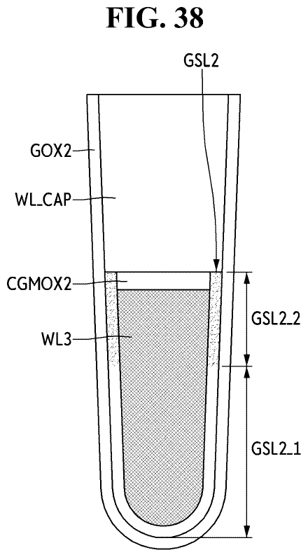

Referring to FIG. 38, the semiconductor memory device according to some embodiments may further include a second capping gate metal oxide film CGMOX2.

The second capping gate metal oxide film CGMOX2 may be disposed on an upper face of the third word line WL3. The second capping gate metal oxide film CGMOX2 may come into contact with the third word line WL3.

The second capping gate metal oxide film CGMOX2 may include a third metal oxide that is an oxide of a third metal element included in the third word line WL3.

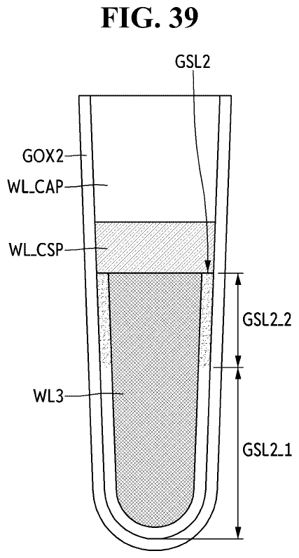

Referring to FIG. 39, in the semiconductor memory device according to some embodiments, the buried cell gate structure may further include a gate capping conductive film WL_CSP.

The gate capping conductive film WL_CSP may be disposed on the third word line WL3. The gate capping conductive film WL_CSP may extend along an upper face of the third word line WL3. The gate capping conductive film WL_CSP may include, for example, but not limited to, polysilicon or polysilicon-germanium.

The gate capping layer WL_CAP may be disposed on the gate capping conductive film WL_CSP. The gate capping layer WL_CAP may be disposed inside the cell gate trench WL_T.

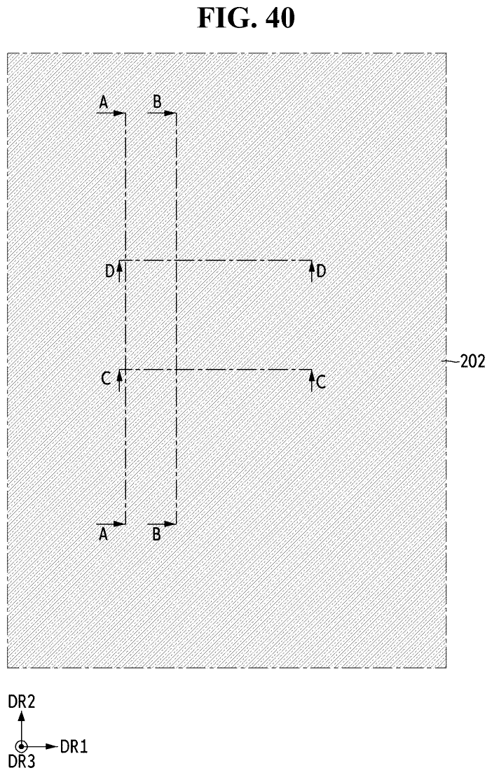

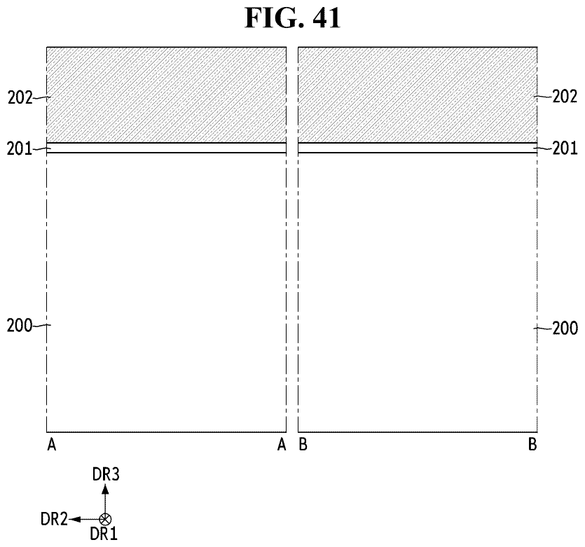

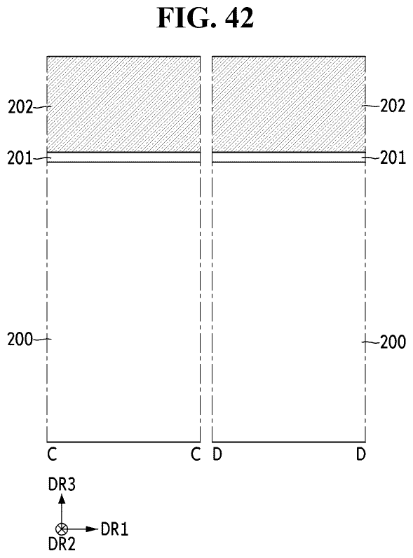

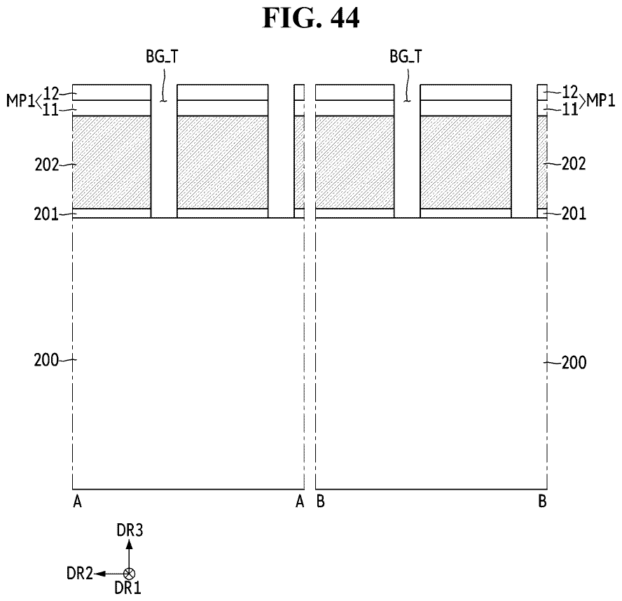

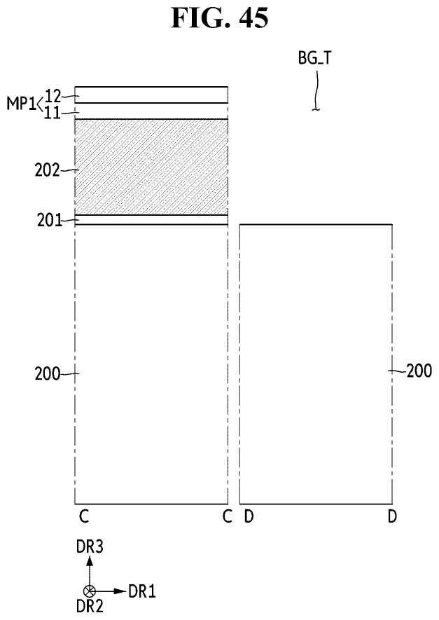

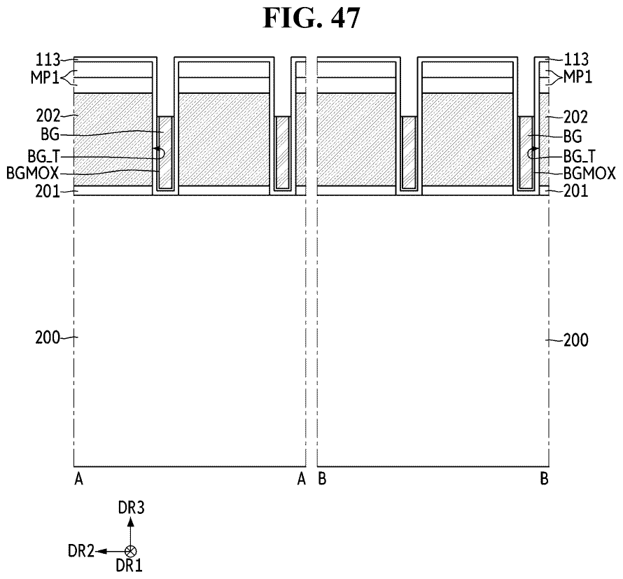

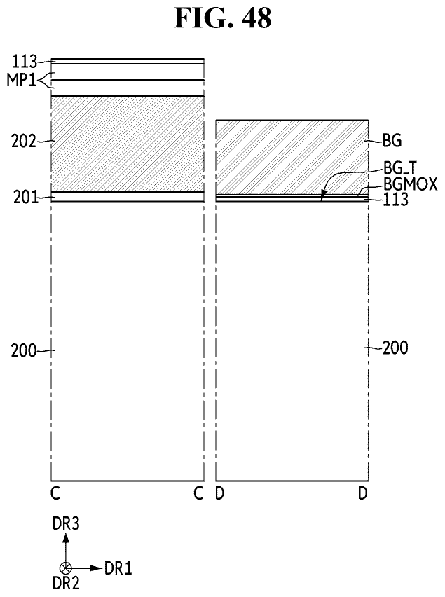

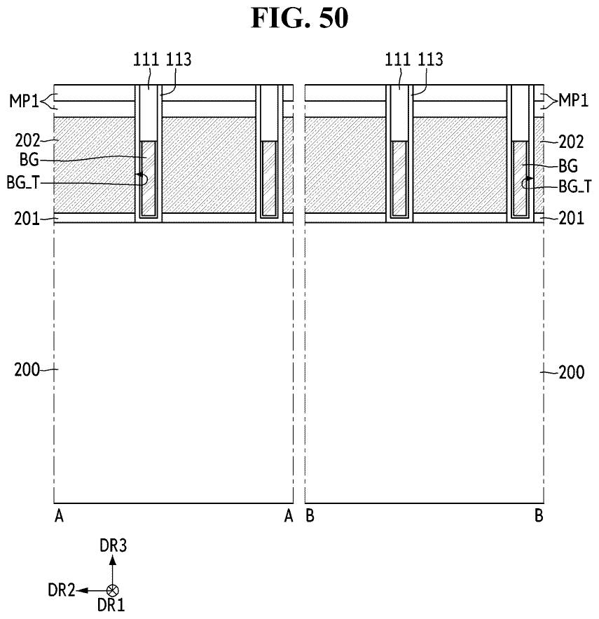

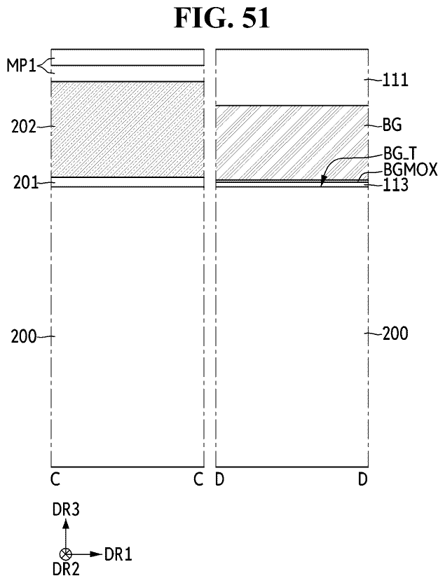

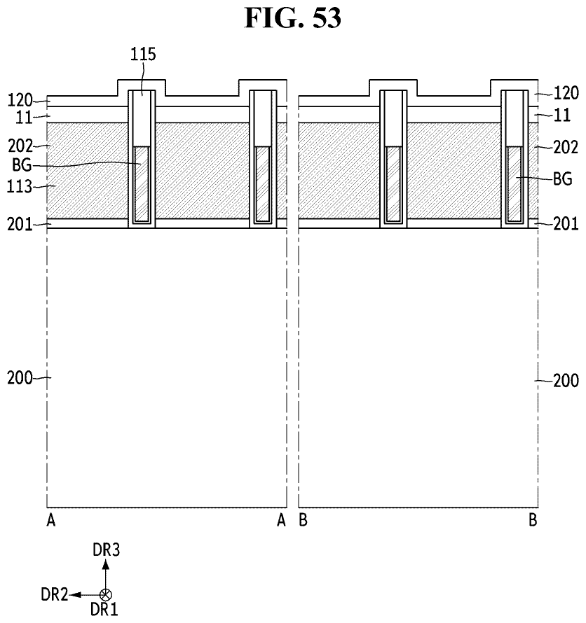

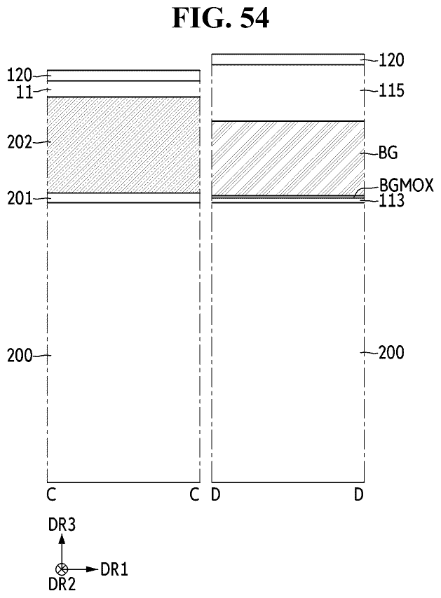

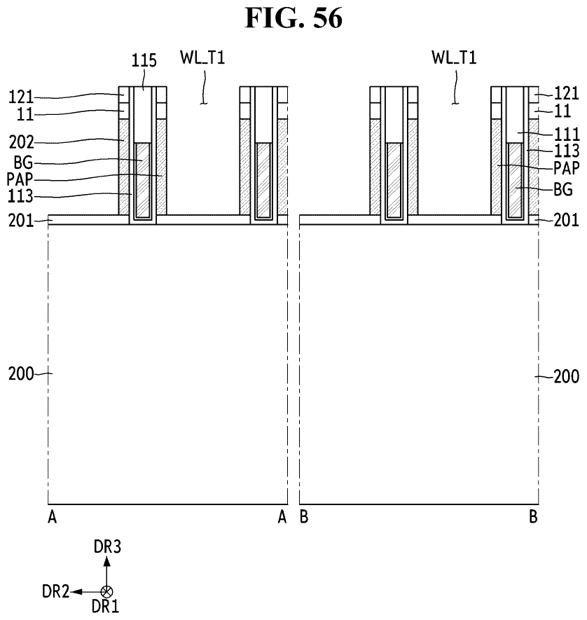

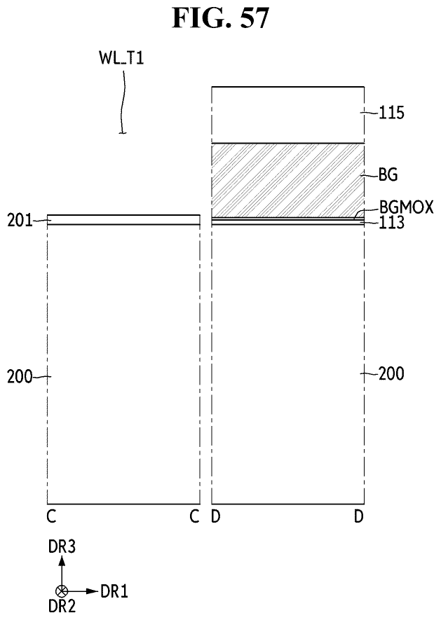

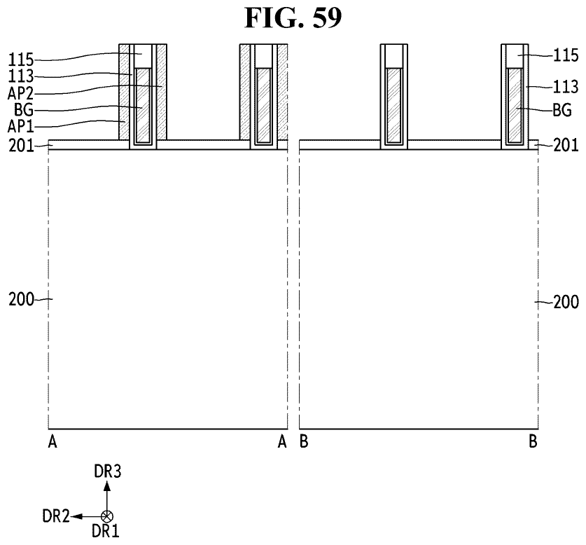

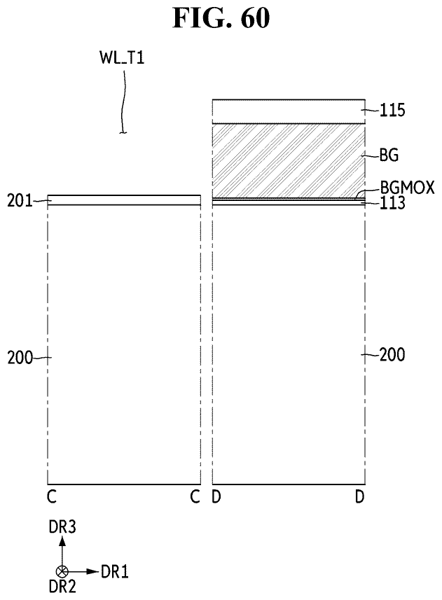

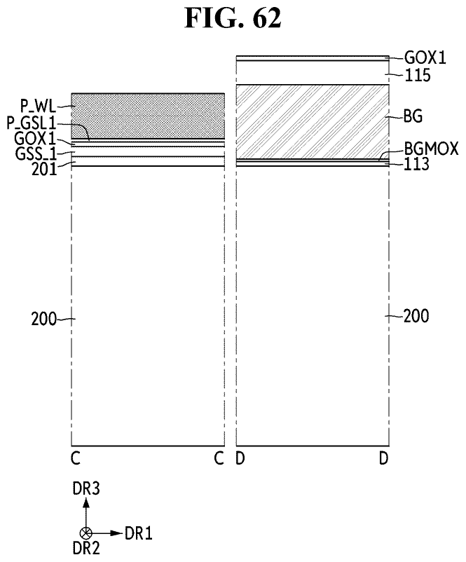

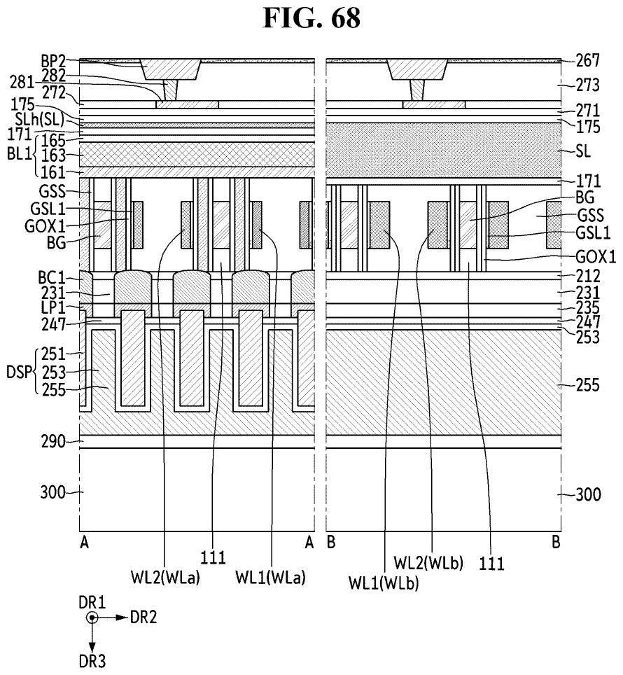

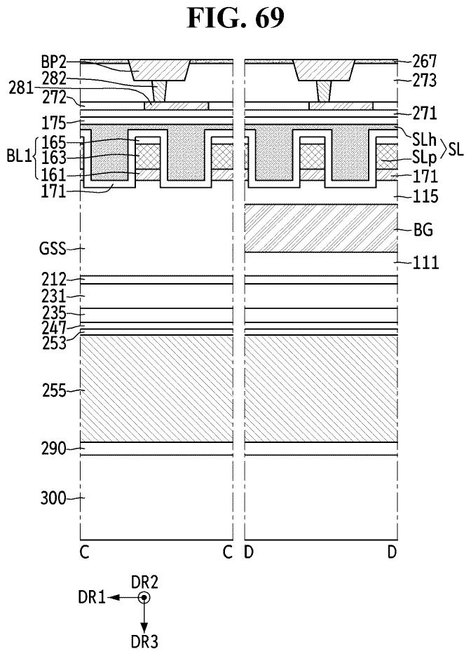

FIGS. 40-69 are intermediate step diagrams for explaining a method for fabricating a semiconductor memory device according to some embodiments.

Referring to FIGS. 40, 41, and 42, a sub-substrate structure which includes a first sub-substrate 200, a buried insulating film 201, and an active layer 202 may be provided.

The buried insulating film 201 and the active layer 202 may be provided on the first sub-substrate 200. The first sub-substrate 200, the buried insulating film 201 and the active layer 202 may be a silicon-on-insulator substrate (i.e., SOI substrate). The first sub-substrate 200 may be a semiconductor substrate. The first sub-substrate 200 may be, for example, a silicon substrate, a germanium substrate, and/or a silicon-germanium substrate. In the following description, the first sub-substrate 200 will be explained as a silicon substrate.

The buried insulating film 201 may be a buried oxide (BOX) formed by a SIMOX (separation by implanted oxygen) method or a bonding and layer transfer method. In contrast, the buried insulating film 201 may be an insulating film formed by a chemical vapor deposition method. The buried insulating film 201 may include, for example, a silicon oxide film, a silicon nitride film, a silicon oxynitride film, and/or a low dielectric constant insulating film.

The active layer 202 may be a single crystal semiconductor film. The active layer 202 may be, for example, a single crystal silicon substrate, a germanium substrate, and/or a silicon-germanium substrate. The active layer 202 may have a first face and a second face that are opposite to each other in the third direction DR3, and the second face of the active layer 202 may come into contact with the buried insulating film 201.

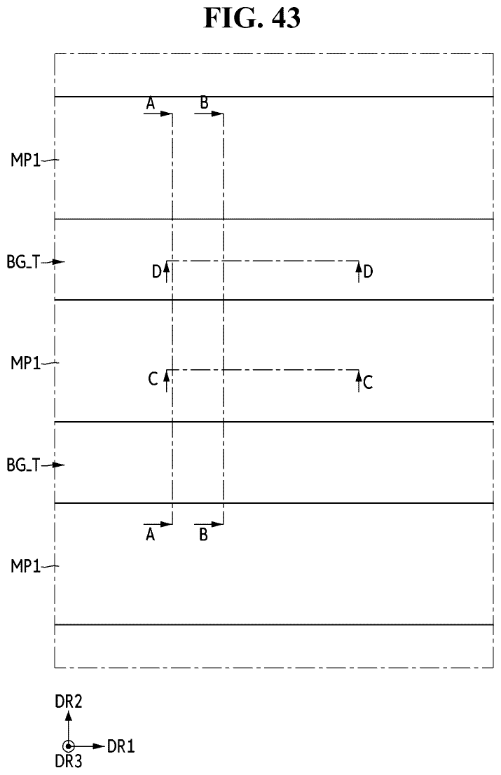

Referring to FIGS. 43-45, a mask pattern MPI may be formed on the active layer 202.

The mask pattern MPI may have linear openings extending along the first direction DR1. The mask pattern MPI may include a first lower mask film 11 and a first upper mask film 12 that are stacked in sequence. The first upper mask film 12 may be formed of a material that has etching selectivity with respect to the first lower mask film 11. As an example, although the first lower mask film 11 may include silicon oxide, and the first upper mask film 12 may include silicon nitride, the embodiment is not limited thereto.

Subsequently, the active layer 202 may be anisotropically etched, using the mask pattern MPI as an etching mask. Accordingly, back gate trenches BG_T extending in the first direction DR1 may be formed on the active layer 202. The back gate trenches BG_T may expose the buried insulating film 201, and may be spaced apart at regular intervals in the second direction DR2.

At least a part of the buried insulating films 201 may be removed, while the back gate trench BG_T is being formed.

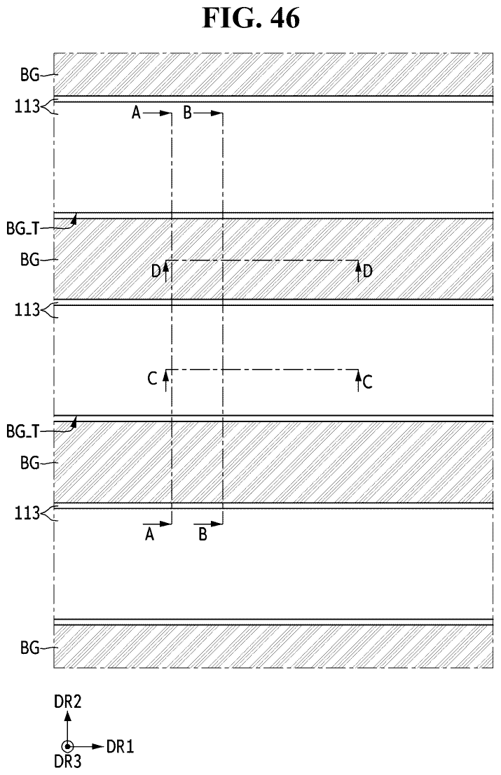

Referring to FIGS. 46 to 48, the back gate insulating film 113 and the back gate electrodes BG may be formed inside the back gate trench BG_T.

More specifically, the back gate insulating film 113 may be formed along the side wall and bottom face of the back gate trench BG_T and the upper face of the mask pattern MPI. A back gate conductive film may be formed on the back gate insulating film 113. The back gate conductive film may fill the back gate trench BG_T. Subsequently, the back gate conductive film may be isotropically etched to form the back gate electrodes BG extending in the first direction DR1. The back gate electrodes BG may partially fill the back gate trench BG_T.

The back gate metal oxide film BGMOX may be formed along the boundary between the back gate insulating film 113 and the back gate electrode BG. The back gate metal oxide film BGMOX may be formed by oxidation of a part of the back gate electrode BG.

Meanwhile, according to some embodiments, a gas phase doping (GPD) process or a plasma doping (PLAD) process may be performed, before forming the back gate insulating film 113. The active layer 202 exposed by the back gate trench BG_T may be doped with impurities through the aforementioned process.

The back gate metal oxide film BGMOX may not be formed along the boundary between the back gate insulating film 113 and the back gate electrode BG.

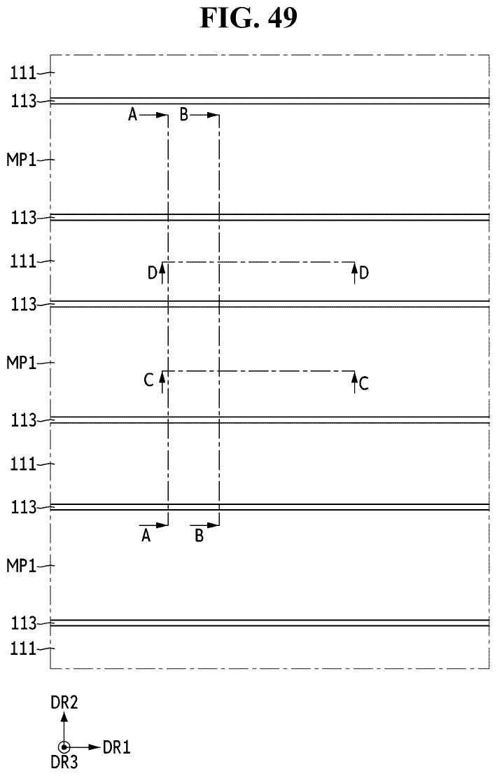

Referring to FIGS. 49-51, the back gate separation patterns 111 may be formed on the back gate electrode BG.

The back gate separation pattern 111 may fill the remainder of the back gate trench BG_T. When the back gate separation pattern 111 and the back gate insulating film 113 are formed of the same material (for example, silicon oxide), the back gate insulating film 113 on the upper face of the mask pattern MPI may be removed, while the back gate separation pattern 111 is being formed.

Meanwhile, before forming the back gate separation pattern 111, a gas phase doping (GPD) process or a plasma doping (PLAD) process may be performed. The active layer 202 may be doped with impurities through the back gate trench BG_T in which the back gate electrode BG is formed, accordingly.

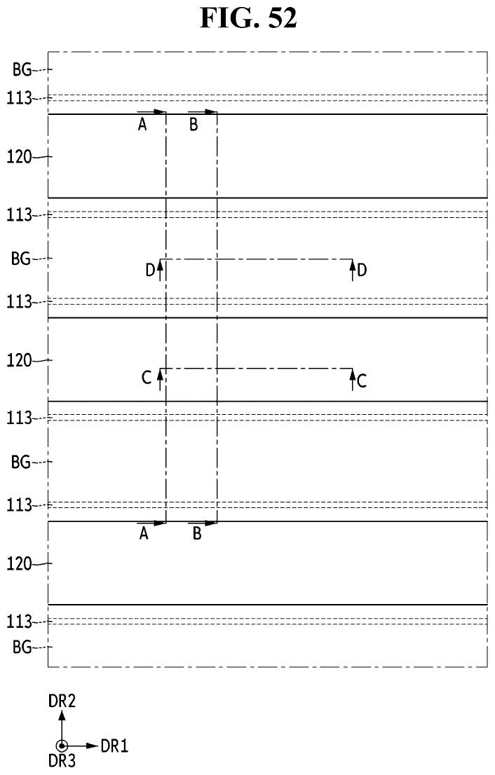

Referring to FIGS. 52-54, after forming the back gate separation patterns 111, the first upper mask film 12 may be removed.

The back gate separation patterns 111 may have a shape that protrudes upward beyond the upper face of the first lower mask film 11.

Next, a spacer film 120 may be formed along the upper face of the first lower mask film 11, the side walls of the back gate insulating patterns 113, and the upper faces of the back gate separation patterns 111. The spacer film 120 may be formed to have a uniform thickness. The widths of the active patterns of the vertical channel transistors may be determined depending on the deposited thickness of the spacer film 120.

The spacer film 120 may be formed of an insulating material. The spacer film 120 may include, for example, silicon oxide, silicon oxynitride, silicon nitride, silicon carbide (SIC), silicon carbon nitride film (SiCN), combinations thereof, and the like.

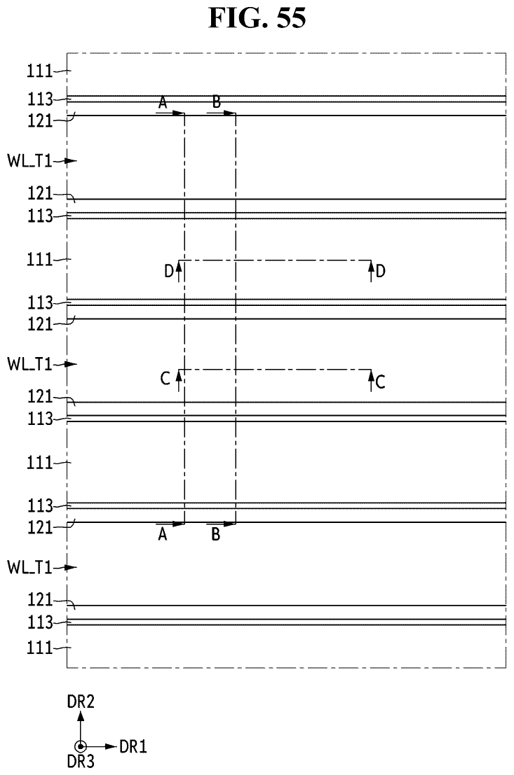

Referring to FIGS. 55, 56, and 57, a pair of spacer patterns 121 may be formed on the side walls of the back gate insulating film 113, by performing an anisotropic etching process on the spacer film 120.

The anisotropic etching process may be performed on the active layer 202, by using the spacer pattern 121 as an etching mask. Accordingly, a pair of pre-active patterns PAP separated from each other may be formed on both sides of each back gate insulating film 113. As the pre-active patterns PAP are formed, the buried insulating film 201 may be exposed.

The pre-active patterns PAP may extend in the first direction DR1 along with the back gate electrode BG. While the pre-active patterns PAP are being formed, a word line trench WL_T1 may be formed between the pre-active patterns PAP adjacent to each other in the second direction DR2.

Referring to FIGS. 55-60, a sacrificial film which fills the word line trench WL_T1 may be formed. A pattern mask may be formed on the sacrificial film. The pattern mask may have a line form extending in the second direction DR2. As an example, the pattern mask may have the line form extending in the diagonal direction with respect to the first direction DR1 and the second direction DR2. The sacrificial film may be etched using the pattern mask as an etching mask to form sacrificial openings inside the sacrificial film.

By etching the pre-active patterns PAP exposed to the sacrificial openings, the first active pattern AP1 and the second active pattern AP2 may be formed on both sides of the back gate electrode BG. The first active patterns AP1 may be formed on the first side wall of the back gate electrode BG to be spaced apart from each other in the first direction DR1. The second active patterns AP2 may be formed on the second side wall of the back gate electrode BG to be spaced apart from each other in the first direction DR1. Because the first active pattern AP1 and the second active pattern AP2 are formed, the sacrificial openings may expose a part of the back gate insulating film 113.

Thereafter, the sacrificial film, the pattern mask, and the spacer pattern 121 may be removed. The first lower mask film 11 may remain on the first active pattern AP1 and the second active pattern AP2. The buried insulating film 201 may be exposed.

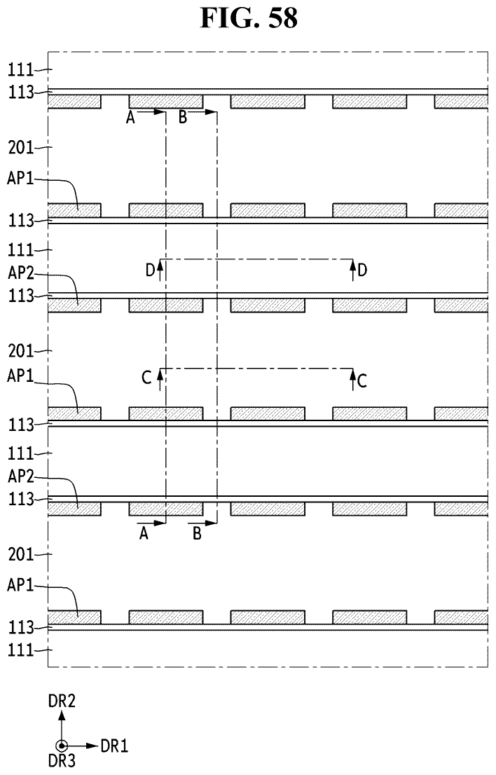

Referring to FIGS. 58 to 62, a gate shielding pattern GSS_1 may be formed inside the word line trench WL_T1.

The gate shielding pattern GSS_1 may partially fill the word line trench WL_T1. The gate shielding pattern GSS_1 may be formed on the buried insulating film 201. In the semiconductor memory device according to some embodiments, the gate shielding pattern GSS_1 may be a part of the gate separation pattern (GSS of FIG. 7).

The first gate insulating film GOX1 may be formed along the side walls of the first active pattern AP1, the side walls of the second active pattern AP2, and the upper face of the back gate separation pattern 111. The first gate insulating film GOX1 may be formed along the upper face of the gate shielding pattern GSS_1.

The first gate insulating pattern GOX1 may be formed, but not limited to, using at least one of physical vapor deposition (PVD), thermal chemical vapor deposition (thermal CVD), low-pressure chemical vapor deposition (LP-CVD), plasma enhanced chemical vapor deposition (PE-CVD) or atomic layer deposition (ALD) techniques.

The gate shielding pattern 145 may not be formed before the first gate insulating pattern GOX1 is formed.

Next, the first pre-gate liner P_GSL1 and the pre-word line pattern P_WL may be formed on the first gate insulating film GOX1. The first pre-gate liner P_GSL1 may be formed along the boundary between the first pre-word line pattern P_WL and the first gate insulating film GOX1.

The first pre-gate liner P_GSL1 may include silicon. For example, the first pre-gate liner P_GSL1 may include a silicon film.

More specifically, a pre-gate liner film may be formed along the profile of the first gate insulating film GOX1. The pre-word line film may be formed on the pre-gate liner film. The pre-word line film may fill the word line trench WL_T1. Next, a part of the pre-gate liner film and a part of the pre-word line film may be etched to form the first pre-gate liner P_GSL1 and the pre-word line pattern P_WL.

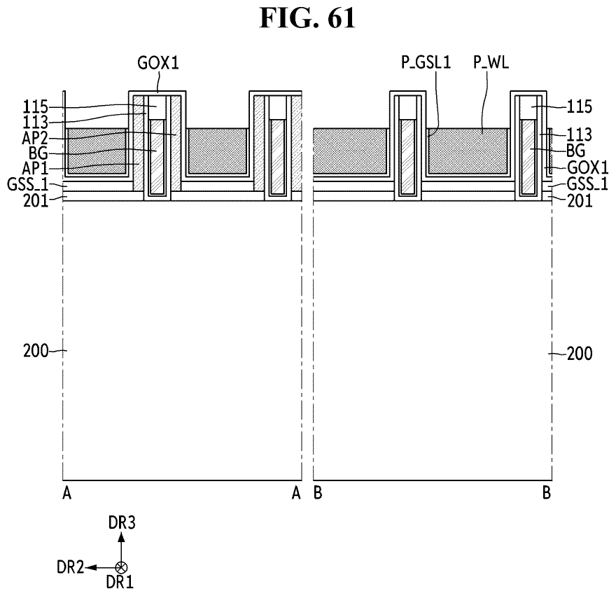

Referring to FIGS. 61, 62, and 63, a first impurity element may be doped into a part of the first pre-gate liner P_GSL1, using an impurity implantation process 50.

A part of the first pre-gate liner P_GSL1 may be doped with the first impurity element to form a second pre-gate liner P_GSL2.

As an example, the impurity implantation process 50 may include a gas phase doping (GPD) process. The second pre-gate liner P_GSL2 may be formed using the gas phase doping process.

As an example, the impurity implantation process 50 may include an ion implantation (IIP) process. The second pre-gate liner P_GSL2 may be formed using the ion implantation process. When the first impurity element is doped into a part of the first pre-gate liner P_GSL1 using the ion implantation process, an ion implantation blocking film may be formed on the pre-word line pattern P_WL and the first gate insulating film GOX1. However, the present disclosure is not limited thereto. The ion implantation blocking film may include, but not limited to, at least one of silicon oxide and silicon nitride.

While the back gate electrode BG shown in FIGS. 46-48 is being formed, the back gate liner (BGSL of FIGS. 14, 15, and 16) doped with the second impurity element may be formed through the method described using FIGS. 61, 62, and 63.

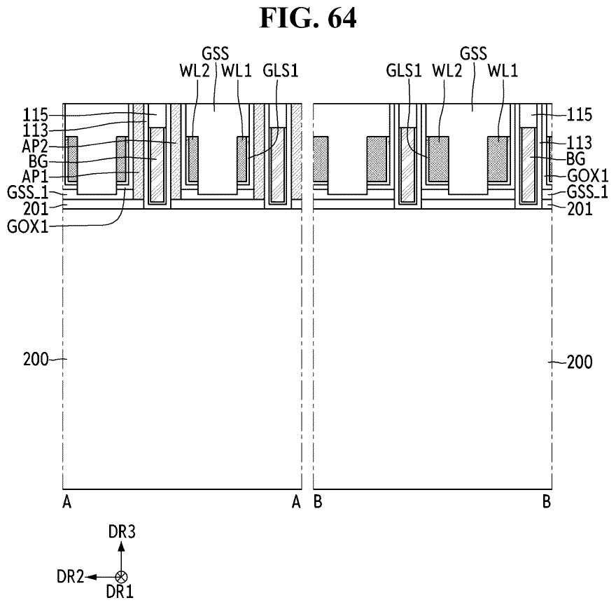

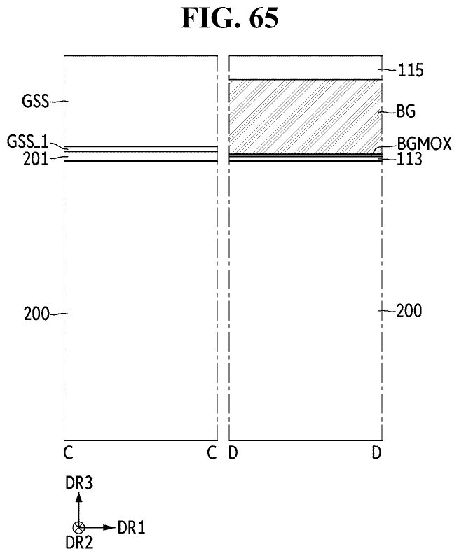

Referring to FIGS. 64 and 65, the pre-word line pattern P_WL may be patterned to form the first word line WL1 and the second word line WL2.

While the first word line WL1 and the second word line WL2 are being formed, the second pre-gate liner P_GSL2 may be patterned. The first gate liner GSL1 may be formed, accordingly.

The pre-word line pattern P_WL may be formed, for example, using an anisotropic etching process. Depending on how the pre-word line pattern P_WL is patterned, the width of the first word line WL1 in the second direction DR2 may be the same as or different from the width of the second word line WL2 in the second direction DR2.

As an example, after forming the first and second word lines WL1 and WL2, the gas phase doping (GPD) process or the plasma doping (PLAD) process may be performed. As a result, impurities may be doped into the first and second active patterns AP1 and AP2 through the first gate insulating film GOX1 exposed by the first and second word lines WL1 and WL2.

Next, the gate separation pattern GSS may be formed on the first word line WL1 and the second word line WL2. For example, the upper face of the gate separation pattern GSS may be disposed on the same plane as the upper face of the back gate capping pattern 115.

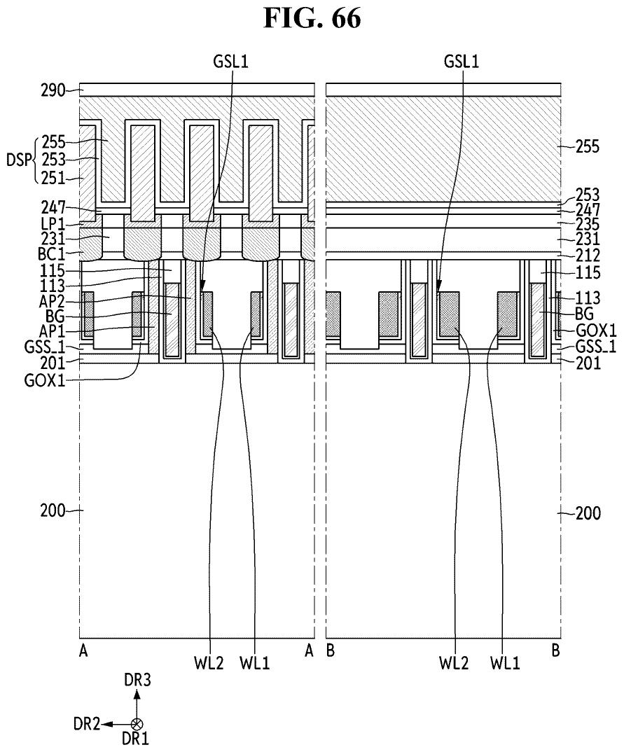

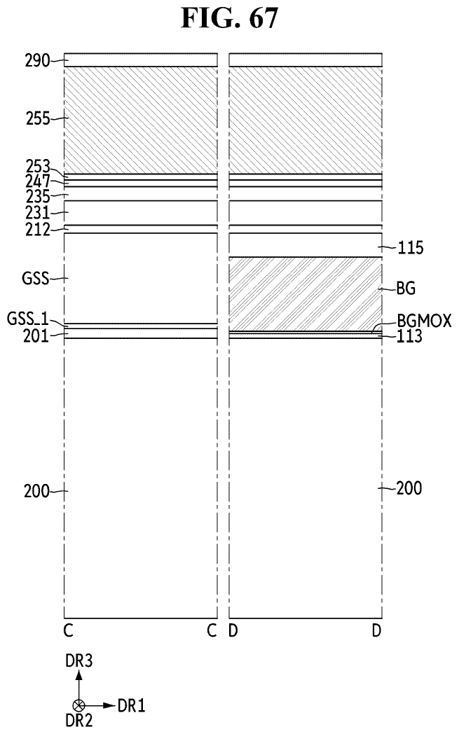

Referring to FIGS. 66 and 67, contact holes for exposing the first active pattern AP1 and the second active pattern AP2 may be formed inside the contact etching stop film 212 and the contact interlayer insulating film 231.

The first contact pattern BC1 may be formed inside the contact hole. The first contact patterns BC1 may be formed on the first active pattern AP1 and the second active pattern AP2. The first contact patterns BC1 may be connected to the first active pattern AP1 and the second active pattern AP2. The data storage patterns DSP may be formed on the first contact pattern BC1.

Next, the cell upper insulating film 290 may be formed on the data storage pattern DSP.

Referring to FIGS. 66-69, the first sub-substrate 200 on which the back gate electrodes BG, the word lines WL1 and WL2, the active patterns AP1 and AP2, and the data storage patterns DSP are formed may be bonded to the second sub-substrate 300.

The back gate electrodes BG, the word lines WL1 and WL2, the active patterns AP1 and AP2, and the data storage patterns DSP may be disposed between the first sub-substrate 200 and the second sub-substrate 300.

Although not shown, the first sub-substrate 200 and the second sub-substrate 300 may be bonded, using a bonding adhesive film.

As an example, the second sub-substrate 300 may be a semiconductor substrate. As an example, the second sub-substrate 300 may be an insulating substrate including an insulating material.

Subsequently, after bonding the first sub-substrate 200 and the second sub-substrate 300, a back lapping process for removing the first sub-substrate 200 may be performed.

Removal of the first sub-substrate 200 may include sequentially performing a grinding process and a wet etching process to expose the buried insulating layer 201. The first sub-substrate 200 may be removed to expose a part of the back gate insulating film 113.

Next, the buried insulating layer 201 may be removed to expose the first active pattern AP1 and the second active pattern AP2. While the buried insulating layer 201 is being removed, a part of the back gate insulating film 113 may be removed. The back gate electrode BG may be exposed, accordingly.

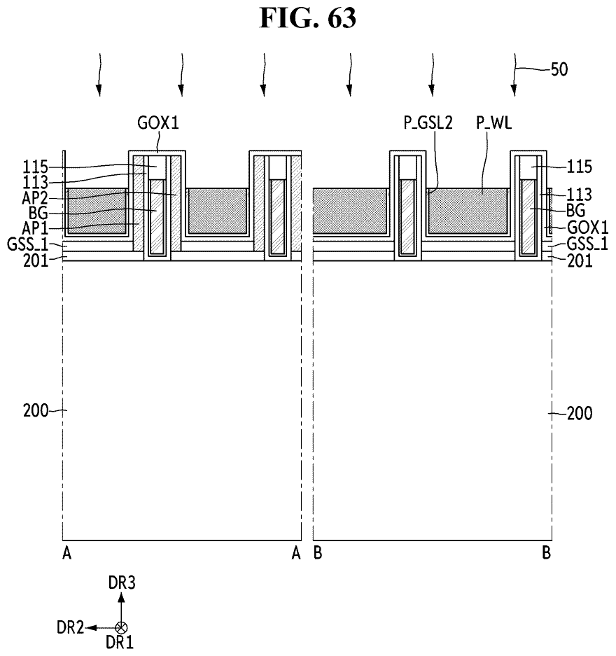

Next, an etch-back process may be performed to remove a part of the back gate electrode BG. A back gate capping pattern 115 may be formed on the recessed back gate electrode BG. Although not shown, before the back gate capping pattern 115 is formed, a back gate liner (BGSL of FIGS. 17 and 18) doped with a second impurity element may be formed through the method described using FIG. 63.

In addition, the gate shielding pattern (GSS_1 of FIG. 66) may be removed. A part of the first gate insulating film GOX1 and a part of the first gate liner GSL1 may be removed to expose the first word line WL1 and the second word line WL2. A part of the gate separation pattern GSS may be formed on the exposed first and second word lines WL1 and WL2.

Although not shown, before the part of the gate separation pattern GSS is formed, the first gate liner GSL1 may be doped with a first impurity element through the method described using FIG. 63.

Next, the first bit line BL1 extending in the second direction DR2 may be formed on the first active pattern AP1 and the second active pattern AP2. The shielding conductive pattern SL may be formed on the first bit line BL1. The shielding insulating capping film 175 may be formed on the shielding conductive pattern SL.

Next, the first cell lower insulating film 271 may be formed on the shielding insulating capping film 175. The second cell lower insulating film 272 may be formed on the first cell lower insulating film 271. The cell connecting wiring 281 may be formed in the second cell lower insulating film 272. The third cell lower insulating film 273 may be formed on the second cell lower insulating film 272. The upper pad plug 282 and the upper bonding pad BP2 may be formed inside the third cell lower insulating film 273.

Next, referring to FIGS. 23 and 24, the substrate 100 on which the peri-gate structure PG, the first peri-connecting structures 242a and 242b, the second peri-connecting structures 243a and 243b, the lower bonding pad BP1, and the lower pad plug 244 are formed may be bonded to the second sub-substrate 300.

The second sub-substrate 300 and the substrate 100 may be bonded, using a bonding adhesive film 267. The second sub-substrate 300 and the substrate 100 may be bonded without the bonding adhesive film 267.

Next, the second sub-substrate 300 may be removed.

Unlike the aforementioned example, the first bit line BL1 may be formed before bonding the first sub-substrate 200 and the second sub-substrate 300. In such a case, the data storage pattern DSP may be formed after bonding the first sub-substrate 200 and the second sub-substrate 300.

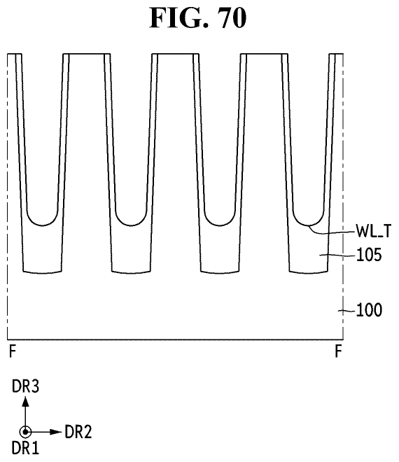

FIGS. 70-73 are diagrams for explaining intermediate steps of a method for fabricating a semiconductor memory device according to some embodiments.

Referring to FIG. 70, the element separation film 105 may be formed inside the substrate 100.

The element separation film 105 may define a cell active region (ACT of FIG. 32).

Next, a cell gate trench WL_T may be formed. The cell gate trench WL_T may be formed in the element separation film 105. Although not shown, the cell gate trench WL_T may be formed inside the substrate 100.

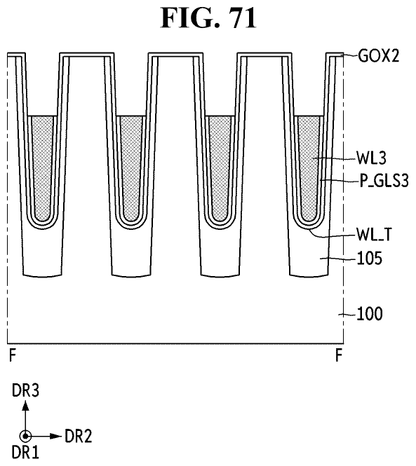

Referring to FIG. 71, a second gate insulating film GOX2 may be formed along a profile of the cell gate trench WL_T.

The second gate insulating film GOX2 may be formed along an upper face of the substrate 100.

The third pre-gate liner P_GSL3 and the third word line WL3 may be formed on the second gate insulating film GOX2. The third pre-gate liner P_GSL3 may be formed along a boundary between the third word line WL3 and the second gate insulating film GOX2.

More specifically, the pre-gate liner film may be formed along the profile of the second gate insulating film GOX2. The pre-word line film may be formed on the pre-gate liner film. The pre-word line film may fill the cell gate trench WL_T. Next, a part of the pre-gate liner film and a part of the pre-word line film may be etched to form a third pre-gate liner P_GSL3 and a third word line WL3.

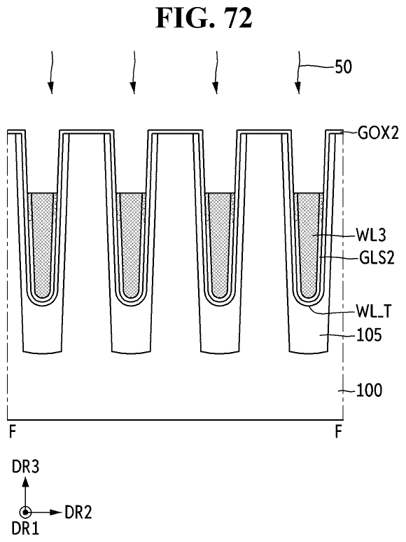

Referring to FIGS. 71 and 72, a third impurity element may be doped into a part of the third pre-gate liner P_GSL3, using an impurity implantation process 50.

A part of the third pre-gate liner P_GSL3 may be doped with the third impurity element to form the second gate liner GSL2.

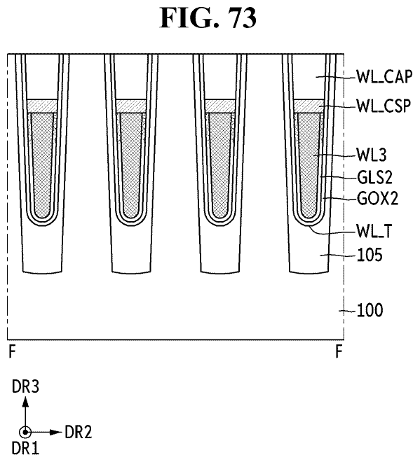

Referring to FIG. 73, a gate capping conductive film WL_CSP may be formed on the third word line WL3.

A gate capping film WL_CAP may be formed on the gate capping conductive film WL_CSP.

The gate capping film WL_CAP and the gate capping conductive film WL_CSP may be formed inside the cell gate trench WL_T. The gate capping film WL_CAP and the gate capping conductive film WL_CSP may fill the cell gate trench WL_T.

The gate capping conductive film WL_CSP may not be formed inside the cell gate trench WL_T.

Although embodiments of the present disclosure have been described with reference to the accompanying drawings, the present disclosure is not limited to the above embodiments and may be implemented in various different forms. A person skilled in the art will understand that the present disclosure may be practiced in other concrete forms without departing from the technical scope of the present disclosure. Therefore, it will be understood that the embodiments as described above is not restrictive but illustrative in all respects.

What is claimed is:

1. A semiconductor memory device comprising:
a channel region;
a word line that extends in a first direction;
a gate insulating film between the channel region and the word line; and
a gate liner between the gate insulating film and the word line,
wherein the gate liner includes silicon,
wherein the gate liner includes a first portion and a second portion,
wherein the first portion of the gate liner is free of an impurity element, and
wherein the second portion of the gate liner includes the impurity element.

2. The semiconductor memory device of claim 1, further comprising:
a gate metal oxide film between the gate liner and the word line, wherein the gate metal oxide film includes a metal oxide.

3. The semiconductor memory device of claim 2, wherein the word line includes a metal element, and the metal oxide includes an oxide of the metal element.

4. The semiconductor memory device of claim 1, wherein the gate insulating film is free of the impurity element.

5. The semiconductor memory device of claim 1, further comprising:
a capping gate metal oxide film on a face of the word line, wherein the capping gate metal oxide film includes a metal oxide.

6. The semiconductor memory device of claim 5, wherein the word line includes a metal element, and the metal oxide includes an oxide of the metal element.

7. The semiconductor memory device of claim 1, wherein the impurity element includes at least one of phosphorus (P), arsenic (As), nitrogen (N), or germanium (Ge).

8. The semiconductor memory device of claim 1, wherein the gate liner includes a silicon film.

9. The semiconductor memory device of claim 1, wherein the gate insulating film includes a silicon oxide.

10. The semiconductor memory device of claim 1, wherein the channel region comprises a silicon active pattern that extend in a third direction that is perpendicular to the first direction,
wherein the silicon active pattern includes a first side wall and a second side wall that are opposite to each other in a second direction that intersects the first direction and is perpendicular to the first direction, and
wherein the word line, the gate insulating film, and the gate liner are on the first side wall of the silicon active pattern.

11. The semiconductor memory device of claim 1, further comprising:
a substrate, having the channel region thereon,
wherein the substrate includes a cell gate trench, and
wherein the word line, the gate insulating film, and the gate liner are disposed inside the cell gate trench.

12. The semiconductor memory device of claim 1, further comprising:
a bit line and a data storage pattern connected to the channel region.

13. A semiconductor memory device comprising:
a bit line that extends in a second direction on a substrate;
an active pattern on the bit line,
the active pattern including a first side wall and a second side wall opposite to each other in the second direction, and a first face and a second face opposite to each other in a third direction that is perpendicular to the second direction, wherein the first face of the active pattern is electrically connected to the bit line;
a word line that is on the first side wall of the active pattern, and extends in a first direction that intersects the second direction and is perpendicular to the third direction;
a gate insulating film that extends along the first side wall of the active pattern, and is in contact with the active pattern;
a gate liner between the gate insulating film and the word line, wherein the gate liner includes a silicon film;
a back gate electrode that is on the second side wall of the active pattern, and extends in the first direction; and
a data storage pattern on the active pattern and electrically connected to the second face of the active pattern,
wherein the gate liner includes a first portion and a second portion,
wherein the first portion of the gate liner is free of a first impurity element, the second portion of the gate liner includes the first impurity element, and the first impurity element includes at least one of phosphorus (P), arsenic (As), nitrogen (N) or germanium (Ge).

14. The semiconductor memory device of claim 13, wherein the gate liner further includes a third portion including the first impurity element, and
wherein the first portion of the gate liner is between the second portion of the gate liner and the third portion of the gate liner.

15. The semiconductor memory device of claim 13, further comprising:
a gate metal oxide film between the gate liner and the word line,
wherein the gate metal oxide film includes a metal oxide of a metal element that is the same as a metal element included in the word line.

16. The semiconductor memory device of claim 13, further comprising:
a back gate insulating film that extends along the second side wall of the active pattern, and is in contact with the active pattern; and
a back gate liner between the back gate insulating film and the back gate electrode, wherein the back gate liner includes silicon, and
wherein the back gate liner includes a first portion that is free of a second impurity element, and a second portion including the second impurity element.

17. The semiconductor memory device of claim 16, wherein the second impurity element includes at least one of phosphorus (P), arsenic (As), nitrogen (N), or germanium (Ge).

18. The semiconductor memory device of claim 16, wherein the back gate liner further includes a third portion including the second impurity element, and the first portion of the back gate liner is between the second portion of the back gate liner and the third portion of the back gate liner.

19. A semiconductor memory device comprising:
a peri-gate structure on a substrate;
a bit line that extends in a second direction on the peri-gate structure;
a shielding conductive pattern on the peri-gate structure including a plurality of shielding conductive line patterns extending in the second direction and adjacent to the bit line;
a first word line that is on the bit line and the shielding conductive pattern, and extends in a first direction that intersects the second direction;
a second word line that is on the bit line and the shielding conductive pattern, extends in the first direction, and is spaced apart from the first word line in the second direction;
a back gate electrode that is between the first word line and the second word line, and extends in the first direction;
a first active pattern on the bit line between the first word line and the back gate electrode;
a second active pattern on the bit line between the second word line and the back gate electrode;
a first gate liner between the first word line and the first active pattern, wherein the first gate liner includes silicon;
a second gate liner between the second word line and the second active pattern wherein the second gate liner includes silicon; and
a data storage pattern that is electrically connected to the first active pattern and the second active pattern,
wherein each of the first gate liner and the second gate liner includes a first portion that is intrinsically pure, and a second portion including an impurity element, and
wherein the impurity element includes at least one of phosphorus (P), arsenic (As), nitrogen (N), or germanium (Ge).

20. The semiconductor memory device of claim 19, further comprising:
a gate metal oxide film between the first word line and the first gate liner, and between the second word line and the second gate liner, and
wherein the gate metal oxide film includes a metal oxide of a metal element that is the same as a metal element included in the first and second word lines.
